(19) United States
(12) Patent Application Publication
(10) Pub. No.: US 2026/0019189 A1
(43) Pub. Date: Jan. 15, 2026

(54) KNOWN BIT EXPLOITATION IN DOWNLINK CHANNEL DECODING

(71) Applicant: QUALCOMM Incorporated, San Diego, CA (US)

(72) Inventors: Ganesh NAGAMANI, Hyderabad (IN); Gowrisankar SOMICHETTY, Bangalore (IN); Srikanth MENON, Bangalore (IN); Ansuman ADHIKARY, Hyderabad (IN); Hobin KIM, San Diego, CA (US); Pavan KAIVARAM, HYDERABAD (IN); Yongle WU, San Diego, CA (US)

(21) Appl. No.: 18/767,694

(22) Filed: Jul. 9, 2024

(51) Int. Cl. H04L 1/00; H04W 28/06; H04W 72/23

(52) U.S. Cl. CPC H04L 1/0036; H04L 1/0091; H04W 28/06; H04W 72/23

(57) ABSTRACT

Methods, systems, and devices for wireless communications are described. A user equipment (UE) may perform at least one decoding procedure that leverages known bits of a downlink control information (DCI) message. The UE may monitor for a DCI message corresponding to a DCI format and may perform multiple decoding procedures in parallel, including a first decoding procedure and a second decoding procedure. The first decoding procedure may be based on a set of received bits of the DCI message. The second decoding procedure may be based on at least a portion of the set of received bits being replaced with one or more known bit values in accordance with the DCI format. That is, the UE may decode a first portion of bits of the DCI and may refrain from decoding a second portion of bits of the DCI that are replaced with the one or more known bits.

### FIELD OF TECHNOLOGY

The following relates to wireless communications, including known bit exploitation in downlink channel decoding.

### BACKGROUND

Wireless communications systems are widely deployed to provide various types of communication content such as voice, video, packet data, messaging, broadcast, and so on. These systems may be capable of supporting communication with multiple users by sharing the available system resources (e.g., time, frequency, and power). Examples of such multiple-access systems include fourth generation (4G) systems such as Long Term Evolution (LTE) systems, LTE-Advanced (LTE-A) systems, or LTE-A Pro systems, and fifth generation (5G) systems which may be referred to as New Radio (NR) systems. These systems may employ technologies such as code division multiple access (CDMA), time division multiple access (TDMA), frequency division multiple access (FDMA), orthogonal FDMA (OFDMA), or discrete Fourier transform spread orthogonal frequency division multiplexing (DFT-S-OFDM). A wireless multiple-access communications system may include one or more base stations, each supporting wireless communication for communication devices, which may be known as user equipment (UE).

### SUMMARY

The described techniques relate to improved methods, systems, devices, and apparatuses that support known bit exploitation in downlink channel decoding. For example, the described techniques provide for a user equipment (UE) to perform at least one decoding procedure that leverages known bits of a downlink control information (DCI) message. For example, the UE may monitor for the DCI message via a wireless channel. The DCI message may correspond to a defined or known DCI format. The UE may perform multiple decoding procedures (e.g., polar decoding procedures) in parallel. For example, the UE may perform a first decoding procedure that is based on a set of received bits of the DCI message. The UE may perform, in parallel with the first decoding procedure, a second decoding procedure that is based on at least a portion of the set of received bits being replaced with one or more known bit values in accordance with the DCI format. That is, the UE may decode one set of bits of the DCI, while refraining from decoding a second set of bits of the DCI that are replaced with the one or more known bits (e.g., the UE may treat the one or more known bits as if they were “frozen” bits).

In some cases, the UE may determine the known bits based on a configuration of the UE or based on the DCI format (e.g., the known bits may be bits that are known to be reserved or padded). Additionally or alternatively, the UE may determine the known bits based on one or more learning schemes and based on previously decoded DCI messages. For example, the UE may determine that a particular subset of bits are “known” if the particular subset of bits is constant for a threshold quantity of DCI messages. The UE may output a result of at least one decoding procedure of the multiple decoding procedures based on performing the multiple decoding procedures. Further, the UE may output the result based on a respective integrity check (e.g., a cyclic redundancy check (CRC)) corresponding to each decoding procedure of the multiple decoding procedures. Thus, the UE may improve reliability of decoding messages from one or more communication channels, thus improving efficiency of decoding downlink messages.

A method for wireless communications by a wireless device is described. The method may include monitoring for a downlink control information message via a wireless channel, the downlink control information message corresponding to a downlink control information format, performing, in parallel, a set of multiple decoding procedures on the downlink control information message, the set of multiple decoding procedures including at least a first decoding procedure that is based on a set of received bits of the downlink control information message and a second decoding procedure that is based on replacing at least a portion of the set of received bits with one or more known bit values in accordance with the downlink control information format, and outputting a result of at least one decoding procedure of the set of multiple decoding procedures based on a respective integrity check corresponding to each decoding procedure of the set of multiple decoding procedures.

A wireless device for wireless communications is described. The wireless device may include one or more memories storing processor executable code, and one or more processors coupled with the one or more memories. The one or more processors may individually or collectively be operable to execute the code to cause the wireless device to monitor for a downlink control information message via a wireless channel, the downlink control information message corresponding to a downlink control information format, perform, in parallel, a set of multiple decoding procedures on the downlink control information message, the set of multiple decoding procedures including at least a first decoding procedure that is based on a set of received bits of the downlink control information message and a second decoding procedure that is based on replacing at least a portion of the set of received bits with one or more known bit values in accordance with the downlink control information format, and output a result of at least one decoding procedure of the set of multiple decoding procedures based on a respective integrity check corresponding to each decoding procedure of the set of multiple decoding procedures.

Another wireless device for wireless communications is described. The wireless device may include means for monitoring for a downlink control information message via a wireless channel, the downlink control information message corresponding to a downlink control information format, means for performing, in parallel, a set of multiple decoding procedures on the downlink control information message, the set of multiple decoding procedures including at least a first decoding procedure that is based on a set of received bits of the downlink control information message and a second decoding procedure that is based on replacing at least a portion of the set of received bits with one or more known bit values in accordance with the downlink control information format, and means for outputting a result of at least one decoding procedure of the set of multiple decoding procedures based on a respective integrity check corresponding to each decoding procedure of the set of multiple decoding procedures.

A non-transitory computer-readable medium storing code for wireless communications is described. The code may include instructions executable by one or more processors to monitor for a downlink control information message via a wireless channel, the downlink control information message corresponding to a downlink control information format, perform, in parallel, a set of multiple decoding procedures on the downlink control information message, the set of multiple decoding procedures including at least a first decoding procedure that is based on a set of received bits of the downlink control information message and a second decoding procedure that is based on replacing at least a portion of the set of received bits with one or more known bit values in accordance with the downlink control information format, and output a result of at least one decoding procedure of the set of multiple decoding procedures based on a respective integrity check corresponding to each decoding procedure of the set of multiple decoding procedures.

In some examples of the method, wireless devices, and non-transitory computer-readable medium described herein, at least a portion of the one or more known bit values includes one or more reserved bits, one or more padded bits, or a combination thereof.

Some examples of the method, wireless devices, and non-transitory computer-readable medium described herein may further include operations, features, means, or instructions for receiving signaling indicating at least a portion of the one or more known bit values prior to monitoring for the downlink control information message.

In some examples of the method, wireless devices, and non-transitory computer-readable medium described herein, receiving the signaling indicating at least the portion of the one or more known bit values may include operations, features, means, or instructions for decoding, prior to the set of multiple decoding procedures, one or more previous downlink control information messages, where the one or more previous downlink control information messages indicate the one or more known bit values.

In some examples of the method, wireless devices, and non-transitory computer-readable medium described herein, receiving the signaling indicating at least the portion of the one or more known bit values may include operations, features, means, or instructions for learning at least the portion of the one or more known bit values according to one or more commonalities between a set of multiple previous downlink control information messages of the one or more previous downlink control information messages.

Some examples of the method, wireless devices, and non-transitory computer-readable medium described herein may further include operations, features, means, or instructions for performing a bitmap generation procedure based on the one or more known bit values, where the second decoding procedure may be based on the bitmap generation procedure.

In some examples of the method, wireless devices, and non-transitory computer-readable medium described herein, the respective integrity check includes a cyclic redundancy check.

In some examples of the method, wireless devices, and non-transitory computer-readable medium described herein, one or both of the first decoding procedure or the second decoding procedure includes a polar decoding procedure.

In some examples of the method, wireless devices, and non-transitory computer-readable medium described herein, the one or more known bit values may be associated with frozen bits in the polar decoding procedure and each known bit value of the one or more known bit values includes a respective logic state of a set of two logic states.

### BRIEF DESCRIPTION OF THE DRAWINGS

FIG. 1 shows an example of a wireless communications system that supports known bit exploitation in downlink channel decoding in accordance with one or more aspects of the present disclosure.

FIG. 2 shows an example of a wireless communications system that supports known bit exploitation in downlink channel decoding in accordance with one or more aspects of the present disclosure.

FIG. 3 shows an example of a learning scheme diagram that supports known bit exploitation in downlink channel decoding in accordance with one or more aspects of the present disclosure.

FIG. 4 shows an example of a process flow that supports known bit exploitation in downlink channel decoding in accordance with one or more aspects of the present disclosure.

FIGS. 5 and 6 show block diagrams of devices that support known bit exploitation in downlink channel decoding in accordance with one or more aspects of the present disclosure.

FIG. 7 shows a block diagram of a communications manager that supports known bit exploitation in downlink channel decoding in accordance with one or more aspects of the present disclosure.

FIG. 8 shows a diagram of a system including a device that supports known bit exploitation in downlink channel decoding in accordance with one or more aspects of the present disclosure.

FIGS. 9 through 11 show flowcharts illustrating methods that support known bit exploitation in downlink channel decoding in accordance with one or more aspects of the present disclosure.

### DETAILED DESCRIPTION

In some wireless communications systems, a user equipment (UE) may receive one or more messages that may include downlink control information (DCI). The UE may decode a DCI based on receiving messages via multiple channels such as a physical downlink control channel (PDCCH) and a physical downlink shared channel (PDSCH). In some systems, a first channel (e.g., PDSCH) may be associated with a lower spectral efficiency than a second channel (e.g., PDCCH). Thus, the first channel may cause a “bottleneck” for the UE that decodes the DCI. This may result in increased latency and decreased data rates at the UE, diminishing the user experience. Thus, solutions which allow a UE to improve performance of communication channels and to improve decoding efficiency are desirable.

In some implementations of the present disclosure, a UE may perform at least one decoding procedure that leverages known bits of a DCI to improve decoding efficiency at the UE. For example, the UE may monitor for a DCI message via a wireless channel. The DCI message may correspond to a known or defined DCI format, such as a DCI format that has been standardized. The UE may perform multiple decoding procedures (e.g., polar decoding procedures) in parallel. For example, the UE may perform a first decoding procedure that is based on a set of received bits of the DCI message. The UE may perform, in parallel with the first decoding procedure, a second decoding procedure that is based on at least a portion of the set of received bits being replaced with one or more known bit values in accordance with the DCI format. That is, the UE may decode one set of bits of the DCI, while refraining from decoding a second set of bits of the DCI that are replaced with the one or more known bits (e.g., the UE may treat the one or more known bits as if they were “frozen” bits in a polar decoding procedure).

In some cases, the UE may determine the known bits based on a configuration of the UE or based on the DCI format (e.g., the known bits may be bits that are known to be reserved or padded). Additionally or alternatively, the UE may determine the known bits based on one or more learning schemes and based on previously decoded DCI messages. For example, the UE may determine that a particular subset of bits are “known” if the particular subset of bits is constant for a threshold quantity of DCI messages. The UE may output a result of at least one decoding procedure of the multiple decoding procedures based on performing the multiple decoding procedures. Further, the UE may output the result based on a respective integrity check (e.g., a cyclic redundancy check (CRC)) corresponding to each decoding procedure of the multiple decoding procedures. Thus, the UE may improve reliability of decoding messages from one or more communication channels, thus improving efficiency of decoding downlink messages.

Aspects of the disclosure are initially described in the context of wireless communications systems. Aspects of the disclosure are then described with reference to a learning scheme diagram and a process flow. Aspects of the disclosure are further illustrated by and described with reference to apparatus diagrams, system diagrams, and flowcharts that relate to known bit exploitation in downlink channel decoding.

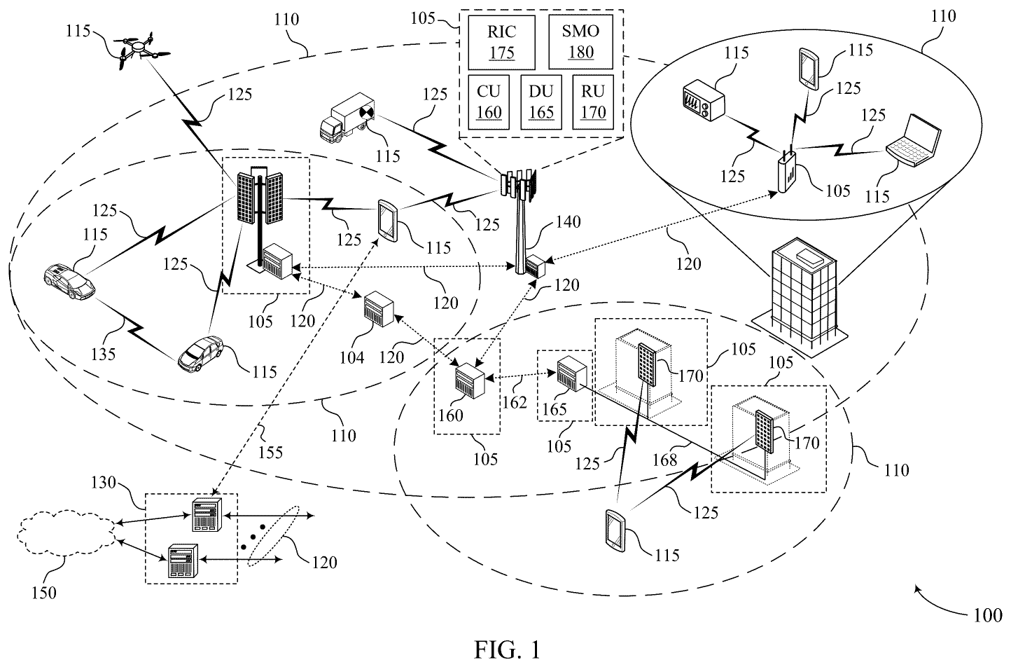

FIG. 1 shows an example of a wireless communications system 100 that supports known bit exploitation in downlink channel decoding in accordance with one or more aspects of the present disclosure. The wireless communications system 100 may include one or more devices, such as one or more network devices (e.g., network entities 105), one or more UEs 115, and a core network 130. In some examples, the wireless communications system 100 may be a Long Term Evolution (LTE) network, an LTE-Advanced (LTE-A) network, an LTE-A Pro network, a New Radio (NR) network, or a network operating in accordance with other systems and radio technologies, including future systems and radio technologies not explicitly mentioned herein.

The network entities 105 may be dispersed throughout a geographic area to form the wireless communications system 100 and may include devices in different forms or having different capabilities. In various examples, a network entity 105 may be referred to as a network element, a mobility element, a radio access network (RAN) node, or network equipment, among other nomenclature. In some examples, network entities 105 and UEs 115 may wirelessly communicate via communication link(s) 125 (e.g., a radio frequency (RF) access link). For example, a network entity 105 may support a coverage area 110 (e.g., a geographic coverage area) over which the UEs 115 and the network entity 105 may establish the communication link(s) 125. The coverage area 110 may be an example of a geographic area over which a network entity 105 and a UE 115 may support the communication of signals according to one or more radio access technologies (RATs).

The UEs 115 may be dispersed throughout a coverage area 110 of the wireless communications system 100, and each UE 115 may be stationary, or mobile, or both at different times. The UEs 115 may be devices in different forms or having different capabilities. Some example UEs 115 are illustrated in FIG. 1. The UEs 115 described herein may be capable of supporting communications with various types of devices in the wireless communications system 100 (e.g., other wireless communication devices, including UEs 115 or network entities 105), as shown in FIG. 1.

As described herein, a node of the wireless communications system 100, which may be referred to as a network node, or a wireless node, may be a network entity 105 (e.g., any network entity described herein), a UE 115 (e.g., any UE described herein), a network controller, an apparatus, a device, a computing system, one or more components, or another suitable processing entity configured to perform any of the techniques described herein. For example, a node may be a UE 115. As another example, a node may be a network entity 105. As another example, a first node may be configured to communicate with a second node or a third node. In one aspect of this example, the first node may be a UE 115, the second node may be a network entity 105, and the third node may be a UE 115. In another aspect of this example, the first node may be a UE 115, the second node may be a network entity 105, and the third node may be a network entity 105. In yet other aspects of this example, the first, second, and third nodes may be different relative to these examples. Similarly, reference to a UE 115, network entity 105, apparatus, device, computing system, or the like may include disclosure of the UE 115, network entity 105, apparatus, device, computing system, or the like being a node. For example, disclosure that a UE 115 is configured to receive information from a network entity 105 also discloses that a first node is configured to receive information from a second node.

In some examples, network entities 105 may communicate with a core network 130, or with one another, or both. For example, network entities 105 may communicate with the core network 130 via backhaul communication link(s) 120 (e.g., in accordance with an S1, N2, N3, or other interface protocol). In some examples, network entities 105 may communicate with one another via backhaul communication link(s) 120 (e.g., in accordance with an X2, Xn, or other interface protocol) either directly (e.g., directly between network entities 105) or indirectly (e.g., via the core network 130). In some examples, network entities 105 may communicate with one another via a midhaul communication link 162 (e.g., in accordance with a midhaul interface protocol) or a fronthaul communication link 168 (e.g., in accordance with a fronthaul interface protocol), or any combination thereof. The backhaul communication link(s) 120, midhaul communication links 162, or fronthaul communication links 168 may be or include one or more wired links (e.g., an electrical link, an optical fiber link) or one or more wireless links (e.g., a radio link, a wireless optical link), among other examples or various combinations thereof. A UE 115 may communicate with the core network 130 via a communication link 155.

One or more of the network entities 105 or network equipment described herein may include or may be referred to as a base station 140 (e.g., a base transceiver station, a radio base station, an NR base station, an access point, a radio transceiver, a NodeB, an eNodeB (eNB), a next-generation NodeB or giga-NodeB (either of which may be referred to as a gNB), a 5G NB, a next-generation eNB (ng-eNB), a Home NodeB, a Home eNodeB, or other suitable terminology). In some examples, a network entity 105 (e.g., a base station 140) may be implemented in an aggregated (e.g., monolithic, standalone) base station architecture, which may be configured to utilize a protocol stack that is physically or logically integrated within one network entity (e.g., a network entity 105 or a single RAN node, such as a base station 140).

In some examples, a network entity 105 may be implemented in a disaggregated architecture (e.g., a disaggregated base station architecture, a disaggregated RAN architecture), which may be configured to utilize a protocol stack that is physically or logically distributed among multiple network entities (e.g., network entities 105), such as an integrated access and backhaul (IAB) network, an open RAN (O-RAN) (e.g., a network configuration sponsored by the O-RAN Alliance), or a virtualized RAN (vRAN) (e.g., a cloud RAN (C-RAN)). For example, a network entity 105 may include one or more of a central unit (CU), such as a CU 160, a distributed unit (DU), such as a DU 165, a radio unit (RU), such as an RU 170, a RAN Intelligent Controller (RIC), such as an RIC 175 (e.g., a Near-Real Time RIC (Near-RT RIC), a Non-Real Time RIC (Non-RT RIC)), a Service Management and Orchestration (SMO) system, such as an SMO system 180, or any combination thereof. An RU 170 may also be referred to as a radio head, a smart radio head, a remote radio head (RRH), a remote radio unit (RRU), or a transmission reception point (TRP). One or more components of the network entities 105 in a disaggregated RAN architecture may be co-located, or one or more components of the network entities 105 may be located in distributed locations (e.g., separate physical locations). In some examples, one or more of the network entities 105 of a disaggregated RAN architecture may be implemented as virtual units (e.g., a virtual CU (VCU), a virtual DU (VDU), a virtual RU (VRU)).

The split of functionality between a CU 160, a DU 165, and an RU 170 is flexible and may support different functionalities depending on which functions (e.g., network layer functions, protocol layer functions, baseband functions, RF functions, or any combinations thereof) are performed at a CU 160, a DU 165, or an RU 170. For example, a functional split of a protocol stack may be employed between a CU 160 and a DU 165 such that the CU 160 may support one or more layers of the protocol stack and the DU 165 may support one or more different layers of the protocol stack. In some examples, the CU 160 may host upper protocol layer (e.g., layer 3 (L3), layer 2 (L2)) functionality and signaling (e.g., Radio Resource Control (RRC), service data adaptation protocol (SDAP), Packet Data Convergence Protocol (PDCP)). The CU 160 (e.g., one or more CUs) may be connected to a DU 165 (e.g., one or more DUs) or an RU 170 (e.g., one or more RUs), or some combination thereof, and the DUs 165, RUs 170, or both may host lower protocol layers, such as layer 1 (L1) (e.g., physical (PHY) layer) or L2 (e.g., radio link control (RLC) layer, medium access control (MAC) layer) functionality and signaling, and may each be at least partially controlled by the CU 160. Additionally, or alternatively, a functional split of the protocol stack may be employed between a DU 165 and an RU 170 such that the DU 165 may support one or more layers of the protocol stack and the RU 170 may support one or more different layers of the protocol stack. The DU 165 may support one or multiple different cells (e.g., via one or multiple different RUs, such as an RU 170). In some cases, a functional split between a CU 160 and a DU 165 or between a DU 165 and an RU 170 may be within a protocol layer (e.g., some functions for a protocol layer may be performed by one of a CU 160, a DU 165, or an RU 170, while other functions of the protocol layer are performed by a different one of the CU 160, the DU 165, or the RU 170). A CU 160 may be functionally split further into CU control plane (CU-CP) and CU user plane (CU-UP) functions. A CU 160 may be connected to a DU 165 via a midhaul communication link 162 (e.g., F1, F1-c, F1-u), and a DU 165 may be connected to an RU 170 via a fronthaul communication link 168 (e.g., open fronthaul (FH) interface). In some examples, a midhaul communication link 162 or a fronthaul communication link 168 may be implemented in accordance with an interface (e.g., a channel) between layers of a protocol stack supported by respective network entities (e.g., one or more of the network entities 105) that are in communication via such communication links.

In some wireless communications systems (e.g., the wireless communications system 100), infrastructure and spectral resources for radio access may support wireless backhaul link capabilities to supplement wired backhaul connections, providing an IAB network architecture (e.g., to a core network 130). In some cases, in an IAB network, one or more of the network entities 105 (e.g., network entities 105 or IAB node(s) 104) may be partially controlled by each other. The IAB node(s) 104 may be referred to as a donor entity or an IAB donor. A DU 165 or an RU 170 may be partially controlled by a CU 160 associated with a network entity 105 or base station 140 (such as a donor network entity or a donor base station). The one or more donor entities (e.g., IAB donors) may be in communication with one or more additional devices (e.g., IAB node(s) 104) via supported access and backhaul links (e.g., backhaul communication link(s) 120). IAB node(s) 104 may include an IAB mobile termination (IAB-MT) controlled (e.g., scheduled) by one or more DUs (e.g., DUs 165) of a coupled IAB donor. An IAB-MT may be equipped with an independent set of antennas for relay of communications with UEs 115 or may share the same antennas (e.g., of an RU 170) of IAB node(s) 104 used for access via the DU 165 of the IAB node(s) 104 (e.g., referred to as virtual IAB-MT (vIAB-MT)). In some examples, the IAB node(s) 104 may include one or more DUs (e.g., DUs 165) that support communication links with additional entities (e.g., IAB node(s) 104, UEs 115) within the relay chain or configuration of the access network (e.g., downstream). In such cases, one or more components of the disaggregated RAN architecture (e.g., the IAB node(s) 104 or components of the IAB node(s) 104) may be configured to operate according to the techniques described herein.

In the case of the techniques described herein applied in the context of a disaggregated RAN architecture, one or more components of the disaggregated RAN architecture may be configured to support test as described herein. For example, some operations described as being performed by a UE 115 or a network entity 105 (e.g., a base station 140) may additionally, or alternatively, be performed by one or more components of the disaggregated RAN architecture (e.g., components such as an IAB node, a DU 165, a CU 160, an RU 170, an RIC 175, an SMO system 180).

A UE 115 may include or may be referred to as a mobile device, a wireless device, a remote device, a handheld device, or a subscriber device, or some other suitable terminology, where the “device” may also be referred to as a unit, a station, a terminal, or a client, among other examples. A UE 115 may also include or may be referred to as a personal electronic device such as a cellular phone, a personal digital assistant (PDA), a tablet computer, a laptop computer, or a personal computer. In some examples, a UE 115 may include or be referred to as a wireless local loop (WLL) station, an Internet of Things (IoT) device, an Internet of Everything (IoE) device, or a machine type communications (MTC) device, among other examples, which may be implemented in various objects such as appliances, vehicles, or meters, among other examples.

The UEs 115 described herein may be able to communicate with various types of devices, such as UEs 115 that may sometimes operate as relays, as well as the network entities 105 and the network equipment including macro eNBs or gNBs, small cell eNBs or gNBs, or relay base stations, among other examples, as shown in FIG. 1.

The UEs 115 and the network entities 105 may wirelessly communicate with one another via the communication link(s) 125 (e.g., one or more access links) using resources associated with one or more carriers. The term “carrier” may refer to a set of RF spectrum resources having a defined PHY layer structure for supporting the communication link(s) 125. For example, a carrier used for the communication link(s) 125 may include a portion of an RF spectrum band (e.g., a bandwidth part (BWP)) that is operated according to one or more PHY layer channels for a given RAT (e.g., LTE, LTE-A, LTE-A Pro, NR). Each PHY layer channel may carry acquisition signaling (e.g., synchronization signals, system information), control signaling that coordinates operation for the carrier, user data, or other signaling. The wireless communications system 100 may support communication with a UE 115 using carrier aggregation or multi-carrier operation. A UE 115 may be configured with multiple downlink component carriers and one or more uplink component carriers according to a carrier aggregation configuration. Carrier aggregation may be used with both frequency division duplexing (FDD) and time division duplexing (TDD) component carriers. Communication between a network entity 105 and other devices may refer to communication between the devices and any portion (e.g., entity, sub-entity) of a network entity 105. For example, the terms “transmitting,” “receiving,” or “communicating,” when referring to a network entity 105, may refer to any portion of a network entity 105 (e.g., a base station 140, a CU 160, a DU 165, a RU 170) of a RAN communicating with another device (e.g., directly or via one or more other network entities, such as one or more of the network entities 105).

Signal waveforms transmitted via a carrier may be made up of multiple subcarriers (e.g., using multi-carrier modulation (MCM) techniques such as orthogonal frequency division multiplexing (OFDM) or discrete Fourier transform spread OFDM (DFT-S-OFDM)). In a system employing MCM techniques, a resource element may refer to resources of one symbol period (e.g., a duration of one modulation symbol) and one subcarrier, in which case the symbol period and subcarrier spacing may be inversely related. The quantity of bits carried by each resource element may depend on the modulation scheme (e.g., the order of the modulation scheme, the coding rate of the modulation scheme, or both), such that a relatively higher quantity of resource elements (e.g., in a transmission duration) and a relatively higher order of a modulation scheme may correspond to a relatively higher rate of communication. A wireless communications resource may refer to a combination of an RF spectrum resource, a time resource, and a spatial resource (e.g., a spatial layer, a beam), and the use of multiple spatial resources may increase the data rate or data integrity for communications with a UE 115.

The time intervals for the network entities 105 or the UEs 115 may be expressed in multiples of a basic time unit which may, for example, refer to a sampling period of Tₛ=1/(Δfₘₐₓ·N_{f}) seconds, for which Δfₘₐₓ may represent a supported subcarrier spacing, and N_{f} may represent a supported discrete Fourier transform (DFT) size. Time intervals of a communications resource may be organized according to radio frames each having a specified duration (e.g., 10 milliseconds (ms)). Each radio frame may be identified by a system frame number (SFN) (e.g., ranging from 0 to 1023).

Each frame may include multiple consecutively-numbered subframes or slots, and each subframe or slot may have the same duration. In some examples, a frame may be divided (e.g., in the time domain) into subframes, and each subframe may be further divided into a quantity of slots. Alternatively, each frame may include a variable quantity of slots, and the quantity of slots may depend on subcarrier spacing. Each slot may include a quantity of symbol periods (e.g., depending on the length of the cyclic prefix prepended to each symbol period). In some wireless communications systems, such as the wireless communications system 100, a slot may further be divided into multiple mini-slots associated with one or more symbols. Excluding the cyclic prefix, each symbol period may be associated with one or more (e.g., N_{f}) sampling periods. The duration of a symbol period may depend on the subcarrier spacing or frequency band of operation.

A subframe, a slot, a mini-slot, or a symbol may be the smallest scheduling unit (e.g., in the time domain) of the wireless communications system 100 and may be referred to as a transmission time interval (TTI). In some examples, the TTI duration (e.g., a quantity of symbol periods in a TTI) may be variable. Additionally, or alternatively, the smallest scheduling unit of the wireless communications system 100 may be dynamically selected (e.g., in bursts of shortened TTIs (sTTIs)).

Physical channels may be multiplexed for communication using a carrier according to various techniques. A physical control channel and a physical data channel may be multiplexed for signaling via a downlink carrier, for example, using one or more of time division multiplexing (TDM) techniques, frequency division multiplexing (FDM) techniques, or hybrid TDM-FDM techniques. A control region (e.g., a control resource set (CORESET)) for a physical control channel may be defined by a set of symbol periods and may extend across the system bandwidth or a subset of the system bandwidth of the carrier. One or more control regions (e.g., CORESETs) may be configured for a set of the UEs 115. For example, one or more of the UEs 115 may monitor or search control regions for control information according to one or more search space sets, and each search space set may include one or multiple control channel candidates in one or more aggregation levels arranged in a cascaded manner. An aggregation level for a control channel candidate may refer to an amount of control channel resources (e.g., control channel elements (CCEs)) associated with encoded information for a control information format having a given payload size. Search space sets may include common search space sets configured for sending control information to UEs 115 (e.g., one or more UEs) or may include UE-specific search space sets for sending control information to a UE 115 (e.g., a specific UE).

In some examples, a network entity 105 (e.g., a base station 140, an RU 170) may be movable and therefore provide communication coverage for a moving coverage area, such as the coverage area 110. In some examples, coverage areas 110 (e.g., different coverage areas) associated with different technologies may overlap, but the coverage areas 110 (e.g., different coverage areas) may be supported by the same network entity (e.g., a network entity 105). In some other examples, overlapping coverage areas, such as a coverage area 110, associated with different technologies may be supported by different network entities (e.g., the network entities 105). The wireless communications system 100 may include, for example, a heterogeneous network in which different types of the network entities 105 support communications for coverage areas 110 (e.g., different coverage areas) using the same or different RATs.

The wireless communications system 100 may be configured to support ultra-reliable communications or low-latency communications, or various combinations thereof. For example, the wireless communications system 100 may be configured to support ultra-reliable low-latency communications (URLLC). The UEs 115 may be designed to support ultra-reliable, low-latency, or critical functions. Ultra-reliable communications may include private communication or group communication and may be supported by one or more services such as push-to-talk, video, or data. Support for ultra-reliable, low-latency functions may include prioritization of services, and such services may be used for public safety or general commercial applications. The terms ultra-reliable, low-latency, and ultra-reliable low-latency may be used interchangeably herein.

In some examples, a UE 115 may be configured to support communicating directly with other UEs (e.g., one or more of the UEs 115) via a device-to-device (D2D) communication link, such as a D2D communication link 135 (e.g., in accordance with a peer-to-peer (P2P), D2D, or sidelink protocol). In some examples, one or more UEs 115 of a group that are performing D2D communications may be within the coverage area 110 of a network entity 105 (e.g., a base station 140, an RU 170), which may support aspects of such D2D communications being configured by (e.g., scheduled by) the network entity 105. In some examples, one or more UEs 115 of such a group may be outside the coverage area 110 of a network entity 105 or may be otherwise unable to or not configured to receive transmissions from a network entity 105. In some examples, groups of the UEs 115 communicating via D2D communications may support a one-to-many (1:M) system in which each UE 115 transmits to one or more of the UEs 115 in the group. In some examples, a network entity 105 may facilitate the scheduling of resources for D2D communications. In some other examples, D2D communications may be carried out between the UEs 115 without an involvement of a network entity 105.

The core network 130 may provide user authentication, access authorization, tracking, Internet Protocol (IP) connectivity, and other access, routing, or mobility functions. The core network 130 may be an evolved packet core (EPC) or 5G core (5GC), which may include at least one control plane entity that manages access and mobility (e.g., a mobility management entity (MME), an access and mobility management function (AMF)) and at least one user plane entity that routes packets or interconnects to external networks (e.g., a serving gateway (S-GW), a Packet Data Network (PDN) gateway (P-GW), or a user plane function (UPF)). The control plane entity may manage non-access stratum (NAS) functions such as mobility, authentication, and bearer management for the UEs 115 served by the network entities 105 (e.g., base stations 140) associated with the core network 130. User IP packets may be transferred through the user plane entity, which may provide IP address allocation as well as other functions. The user plane entity may be connected to IP services 150 for one or more network operators. The IP services 150 may include access to the Internet, Intranet(s), an IP Multimedia Subsystem (IMS), or a Packet-Switched Streaming Service.

The wireless communications system 100 may operate using one or more frequency bands, which may be in the range of 300 megahertz (MHz) to 300 gigahertz (GHz). Generally, the region from 300 MHz to 3 GHz is known as the ultra-high frequency (UHF) region or decimeter band because the wavelengths range from approximately one decimeter to one meter in length. UHF waves may be blocked or redirected by buildings and environmental features, which may be referred to as clusters, but the waves may penetrate structures sufficiently for a macro cell to provide service to the UEs 115 located indoors. Communications using UHF waves may be associated with smaller antennas and shorter ranges (e.g., less than one hundred kilometers) compared to communications using the smaller frequencies and longer waves of the high frequency (HF) or very high frequency (VHF) portion of the spectrum below 300 MHz.

The wireless communications system 100 may utilize both licensed and unlicensed RF spectrum bands. For example, the wireless communications system 100 may employ License Assisted Access (LAA), LTE-Unlicensed (LTE-U) RAT, or NR technology using an unlicensed band such as the 5 GHz industrial, scientific, and medical (ISM) band. While operating using unlicensed RF spectrum bands, devices such as the network entities 105 and the UEs 115 may employ carrier sensing for collision detection and avoidance. In some examples, operations using unlicensed bands may be based on a carrier aggregation configuration in conjunction with component carriers operating using a licensed band (e.g., LAA). Operations using unlicensed spectrum may include downlink transmissions, uplink transmissions, P2P transmissions, or D2D transmissions, among other examples.

A network entity 105 (e.g., a base station 140, an RU 170) or a UE 115 may be equipped with multiple antennas, which may be used to employ techniques such as transmit diversity, receive diversity, multiple-input multiple-output (MIMO) communications, or beamforming. The antennas of a network entity 105 or a UE 115 may be located within one or more antenna arrays or antenna panels, which may support MIMO operations or transmit or receive beamforming. For example, one or more base station antennas or antenna arrays may be co-located at an antenna assembly, such as an antenna tower. In some examples, antennas or antenna arrays associated with a network entity 105 may be located at diverse geographic locations. A network entity 105 may include an antenna array with a set of rows and columns of antenna ports that the network entity 105 may use to support beamforming of communications with a UE 115. Likewise, a UE 115 may include one or more antenna arrays that may support various MIMO or beamforming operations. Additionally, or alternatively, an antenna panel may support RF beamforming for a signal transmitted via an antenna port.

Beamforming, which may also be referred to as spatial filtering, directional transmission, or directional reception, is a signal processing technique that may be used at a transmitting device or a receiving device (e.g., a network entity 105, a UE 115) to shape or steer an antenna beam (e.g., a transmit beam, a receive beam) along a spatial path between the transmitting device and the receiving device. Beamforming may be achieved by combining the signals communicated via antenna elements of an antenna array such that some signals propagating along particular orientations with respect to an antenna array experience constructive interference while others experience destructive interference. The adjustment of signals communicated via the antenna elements may include a transmitting device or a receiving device applying amplitude offsets, phase offsets, or both to signals carried via the antenna elements associated with the device. The adjustments associated with each of the antenna elements may be defined by a beamforming weight set associated with a particular orientation (e.g., with respect to the antenna array of the transmitting device or receiving device, or with respect to some other orientation).

The wireless communications system 100 may support a UE 115 that monitors for a DCI message via a wireless channel. The DCI message may correspond to a DCI format. The UE 115 may perform multiple decoding procedures in parallel. In some cases, the multiple decoding procedures may be polar decoding procedures. For example, the UE 115 may perform a first polar decoding procedure that is based on a set of received bits of the DCI message. The UE 115 may perform, in parallel with the first polar decoding procedure, a second polar decoding procedure that is based on at least a portion of the set of received bits being replaced with one or more known bit values in accordance with the DCI format. In other words, the UE 115 may decode a first set of bits of the DCI and may obtain a second set of bits of the DCI based on the second set of bits being known bits. For example, the UE 115 may use a set of known bit values for the second set of bits (e.g., rather than decoding the second set of bits).

In some cases, the UE 115 may determine one or more known bit values based on a configuration of the UE 115 or based on the DCI format (e.g., the known bit values may be bits that are known to be reserved or padded). Additionally or alternatively, the UE 115 may determine the known bits based on one or more learning schemes and based on previously decoded DCI messages. For example, the UE 115 may determine that a particular subset of bits are “known” if the particular subset of bits is constant for a threshold quantity of DCI messages. If a set of bit values is constant across multiple DCI messages (e.g., satisfying the threshold quantity), the UE 115 may use the set of bit values as “known” bit values. The UE 115 may output a result of at least one decoding procedure of the multiple decoding procedures based on performing the multiple decoding procedures. Further, the UE 115 may output the result based on a respective integrity check corresponding to each decoding procedure of the multiple decoding procedures. In some cases, the respective integrity check may be a CRC. Thus, the UE 115 may improve reliability of decoding messages from one or more communication channels, improving efficiency of decoding downlink messages.

In some wireless communications systems, a device may have a relatively reduced receive antenna while performing multi-subscriber identity module (MSIM) timing advance (MSIM TA) procedures. The device may thus experience decreased idle mode page performance. A PDCCH spectral efficiency (e.g., a spectral efficiency of a PDCCH received by the device) may have a value somewhat close to a PDSCH spectral efficiency, which may indicate that the PDCCH causes a “bottleneck” in data transmission or decoding at the device.

In some systems, a UE may receive one or more messages that may include a DCI message. The UE may decode the DCI message based on receiving messages via multiple channels such as a PDCCH and a PDSCH. As mentioned, a first channel (e.g., PDSCH) may be associated with a lower spectral efficiency than a second channel (e.g., PDCCH). Thus, the first channel may result in a “bottleneck” for the UE that decodes the DCI. This may result in increased latency and decreased data rates at the UE, diminishing the user experience. Thus, solutions which allow a UE to improve performance of communication channels and to improve decoding efficiency are desirable.

Some wireless communications systems may support multiple DCI formats (e.g., DCI 0_0, DCI 0_1, DCI 0_2, DCI 1_0, DCI 1_2, DCI 2_2, DCI 2_6, or other DCI formats). Contents of a DCI (e.g., DCI field contents) may be based on a type of radio network temporary identify (RNTI) associated with the DCI. For example, the DCI may have a DCI format with CRC scrambled by the type of RNTI. In some cases, one or more fields of the DCI may be set as “reserved bits”. Bits in the one or more fields set as “reserved bits” may be constant for each DCI of the same format (e.g., a given bit may be constantly a ‘1’ or a ‘0’ depending on the DCI format). For example, for paging RNTI (P-RNTI), a DCI may include a non-short message with a DCI format 1_0, and the DCI may include a quantity of eight or six reserved bits (e.g., 8/6 bits). For cell RNTI (C-RNTI), a DCI may indicate a random access channel (RACH) order with a DCI format 1_0, and the DCI may include a quantity of 12 or 10 reserved bits (e.g., 12/10 bits). For system information RNTI (SI-RNTI), a DCI may have a DCI format 1_0, and the DCI may include a quantity of 17 or 15 reserved bits (e.g., 17/15 bits). For random access RNTI (RA-RNTI), or for an RNTI type associated with MsgB of a RACH procedure (e.g., MsgB-RNTI), a DCI may have a DCI format 1_0, and the DCI may include a quantity of 14 or 16 reserved bits (e.g., 17/15 bits). In some wireless communications systems, a device (e.g., a UE or a network entity) may apply zero padding for DCI size alignment. For example, each DCI format may specify fields totaling a respective quantity of bits. To align the DCI formats such that they are each a same size, the device may concatenate a quantity of bits of a same value (e.g., ‘0’) to one or both ends of the DCI formatted bits.

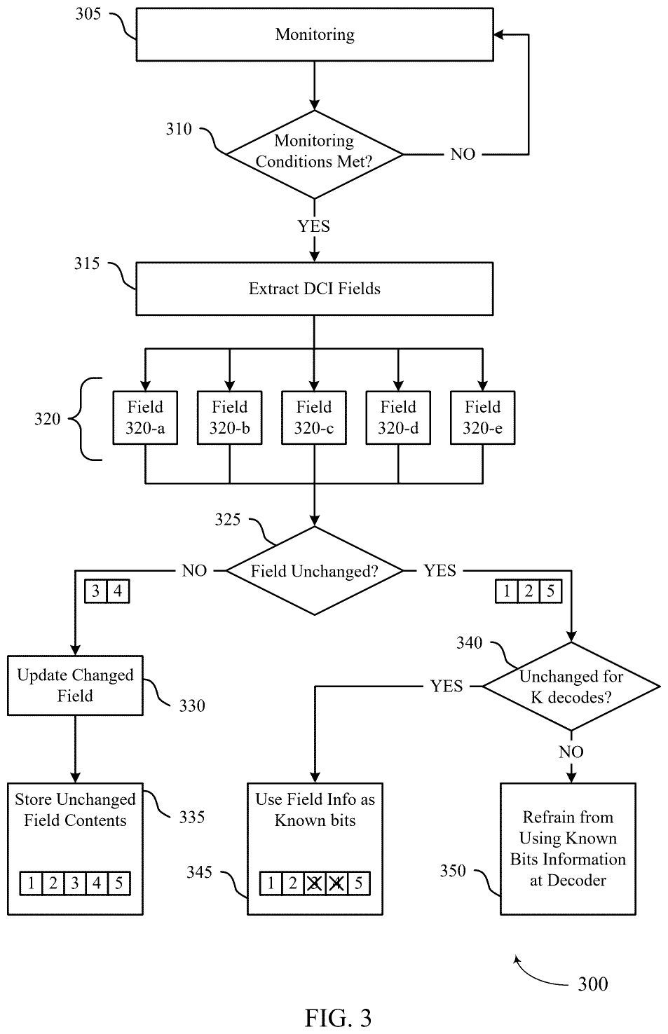

In some implementations, a UE 115 may determine reserved bits or zero-padded bits based on a DCI format and an associated RNTI type of a received DCI. Further, the UE 115 may learn other DCI field contents observed to be unchanged by a network over time (e.g., for a particular deployment). For example, for a non-short message, contents of a P-RNTI DCI 1_0 for a particular field deployment may include a set of known bits (e.g., known to the UE 115). The set of known bits may include bits known to be ‘0’ per a configuration of the network (e.g., 1 bit of a short message indicator field, 8 bits of a short message field, 1 bit of a modulation and coding scheme (MCS) field, and 6 bits from a reserved bits field) and bits known to be ‘1’ per the configuration (e.g., 1 bit of the short message indicator field). Further, the set of known bits may include bits learned to be ‘0’ or ‘1’ based on a learning scheme (e.g., described with reference to FIG. 3). Such learned bits may include bits learned to be ‘0’ (e.g., 1 bit of a virtual resource block to physical resource block field, 1 bit of the MCS field, and one bit of a transport block scale field) and bits learned to be ‘1’ (e.g., 3 bits of the MCS field and 1 bit of the transport block scale field). A set of known bits may be based on factors associated with a given DCI such as a field deployment, a DCI format, an RNTI type, one or more learning schemes, or any combination thereof. In some examples, an unchanged portion of a set of DCI field contents may be classified as known-0 or known-1 bits. The unchanged portion may include reserved bits that are known based on a specification or configuration of the UE 115 or the network, or that are known based on learning from deployment (e.g., a learning scheme).

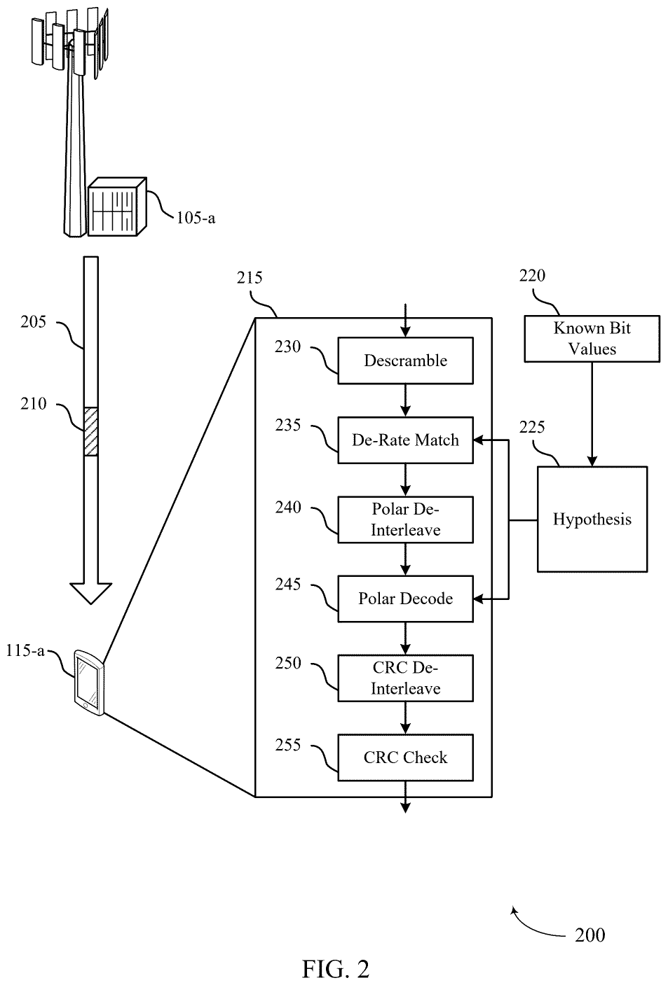

FIG. 2 shows an example of a wireless communications system 200 that supports known bit exploitation in downlink channel decoding in accordance with one or more aspects of the present disclosure. In some cases, the wireless communications system 200 may implement or be implemented by aspects of the wireless communications system 100. For example, the wireless communications system 200 may include one or more UEs 115 (e.g., a UE 115-a) and one or more network entities 105 (e.g., a network entity 105-a), which may be examples of the corresponding devices as described herein. In some cases, the UE 115-a may receive messages from the network entity 105-a via a wireless connection 205 (e.g., a PDCCH, a PDSCH, or both). For example, the UE 115-a may receive, via the wireless connection 205, a DCI message 210. In some examples, the DCI message 210 may include multiple bits, such as PDCCH payload bits.

In some implementations, the UE 115-a may perform one or more procedures, such as a decoding procedure 215. The decoding procedure 215 may include one or more processes that the UE 115-a may perform to decode and check the DCI message 210. In some cases, the UE 115-a may determine known bit values 220 and may perform the decoding procedure 215 based on a hypothesis 225 (e.g., a PDCCH hypothesis) that is in accordance with the known bit values 220. In some examples, the UE 115-a may determine at least a first portion of the known bit values 220 based on determining a set of reserved bits, a set of padded bits, or both, within the DCI message 210. Additionally or alternatively, the UE 115-a may determine at least a second portion of the known bit values 220 based on a learning scheme (e.g., as described with reference to FIG. 3).

At 230, the UE 115-a may perform a descrambling procedure on the DCI message 210. The descrambling procedure may take, as an input, a set of reordered values (e.g., reordered logarithm of the likelihood ratio (LLR) values) corresponding to bits of the DCI message 210. The set of reordered values may be a result of a demodulation procedure and a computation procedure, in which the UE 115-a may generate a set of soft symbols based on signals received via the wireless connection 205. The UE 115-a may then feed the set of soft symbols to an LLR computation unit, where the UE 115-a may convert each soft symbol of a set of soft symbols to a group of LLR values (e.g., the set of reordered values, or soft bits), representing one originally encoded bit mapped to the symbols). Accordingly, the descrambling procedure may output a set of descrambled values.

At 235, the UE 115-a may perform a de-rate match procedure on the descrambled values. In some cases, the de-rate match procedure may be based on the hypothesis 225. For example, the UE 115-a may perform the de-rate match procedure in accordance with the known bit values 220, generating a set of de-rate matched values (e.g., in some cases using the known bit values 220). In some examples, the de-rate match procedure may correspond to a rate match procedure performed at the network entity 105-a to generate the DCI message 210 (e.g., being an inverse or reverse thereof).

At 240, the UE 115-a may perform a first de-interleave procedure on the de-rate matched values (e.g., a polar de-interleave procedure using a subblock deinterleaver) to generate de-interleaved values. For example, the de-interleaved values may serve as an input for a decoding procedure. In some cases, the UE 115-a may de-interleave the de-rate matched values in accordance with an interleave procedure performed at the network entity 105-a (e.g., performing an inverse or reverse process of the interleave procedure at the network entity 105-a).

At 245, the UE 115-a may perform the decoding procedure (e.g., a polar decoding procedure using a polar decoder). In some implementations, the UE 115-a may perform a first decoding procedure, a second decoding procedure, or both. The UE 115-a may perform the first decoding procedure without using the known bit values 220 (based on a hypothesis without regard to the known bit values 220). The first decoding procedure may output a first DCI message 210 (e.g., without replacing bits of the first DCI message 210 with the known bit values 220).

The UE 115-a may perform the second decoding procedure using the known bit values 220 (e.g., based on the hypothesis 225). The second decoding procedure may output a second DCI message 210 (e.g., with an enhancement taking advantage of known bits, or “known-0's” and “known-1's”). For example, the UE 115-a may replace respective bits of the second DCI message 210 with respective known bit values 220 corresponding to the second DCI message 210. In some cases, the UE 115-a may handle the known bit values 220 in the second decoding procedure using techniques associated with “frozen” bits of a polar decoding procedure. For example, the known bit values 220 may be associated with frozen bits in the second decoding procedure (e.g., a polar decoding procedure). In some implementations, a device (such as a UE 115 or a network entity 105) may assign a defined bit value (e.g., ‘0’ or ‘1’) to a frozen bit (e.g., associated with a known bit value) such that the device (or another device) may determine the defined bit value without decoding the associated bit. In some examples as described herein, the UE 115-a may thus determine known bit values corresponding to the second DCI message 210 (e.g., using techniques similar to techniques used to determine frozen bit values of a polar decoding procedure).

At 250, the UE 115-a may perform a second de-interleave procedure using one or more outputs of the polar decoding procedure (e.g., using a CRC deinterleaver). For example, the UE 115-a may perform the second de-interleave procedure using the first DCI message 210 and the second DCI message 210. The second de-interleave procedure may output respective de-interleaved versions of the first DCI message 210 and the second DCI message 210 (e.g., including descrambled, de-rate matched, decoded, and de-interleaved information). Additionally or alternatively, the second de-interleave procedure may output integrity check information (e.g., CRC information) corresponding to the DCI message 210.

At 255, the UE 115-a may perform an integrity check (e.g., a CRC integrity check) on the DCI message 210 using the integrity check information. In some cases, the UE 115-a may perform a first integrity check on the DCI message 210 (e.g., without using the known bit values 220). Additionally or alternatively, the UE 115-a may perform a second integrity check on the DCI message 210 (e.g., using the known bit values 220). In some implementations, the UE 115-a may output a result of one or both of the first and second decoding procedures based on the first and second integrity checks. For example, if the first integrity check indicates that the first decoding procedure was successful (e.g., that the first DCI message includes correct information bits), the UE 115-a may output a result of the first decoding procedure. If the second integrity check indicates that the first decoding procedure was successful, the UE 115-a may output a result of the second decoding procedure. In some examples, the UE 115-a may output that the results of the decoding procedures are the same or different, depending on the respective integrity checks. Accordingly, the UE 115-a may maintain a record (in one or more memories) of whether the second decoding procedure (e.g., using the known bit values 220) was successful.

FIG. 3 shows an example of a learning scheme 300 that supports known bit exploitation in downlink channel decoding in accordance with one or more aspects of the present disclosure. In some cases, the learning scheme 300 may implement or be implemented by aspects of the wireless communications system 100 and the wireless communications system 200. For example, a UE 115 (or another device) may perform a set of operations (e.g., described below) to execute the learning scheme 300. In the following description of the learning scheme 300, the operations may be performed in a different order than the example order shown. Some operations may also be omitted from the learning scheme 300, and other operations may be added to the learning scheme 300. Further, although some operations may be shown to occur at different times for discussion purposes, these operations may actually occur at the same time.

As described herein with reference to FIG. 2, some bits in a message (e.g., PDDCH payload bits) may be known to the UE 115 prior to a decode operation for the message. Some of these “known” bits may be reserved or padded bits. However, other “known” bits may be learned. The learning scheme 300 illustrates a method by which the UE 115 may learn one or more bits such that they become “known” bits for decoding purposes. The UE 115 may utilize these known bits in a decoder (e.g., a PDCCH decoder, a polar decoder) to enhance performance of other information bits of the message. The learning scheme 300 may use a successful decode history to identify unchanged DCI field contents (e.g., known bits). The learning scheme 300 may be based on a threshold quantity of consecutive decodes (e.g., a threshold value K) to enable the UE 115 to use (e.g., take advantage of) the known bits).

At 305, the UE 115 may monitor for a message (or multiple messages) such as a DCI message (e.g., a P-RNTI DCI message, DCI messages with other RNTI types, or a combination thereof). For example, the UE 115 may receive the message from a network entity 105 via one or more channels.

At 310, after receiving the message, the UE 115 may determine whether one or more monitoring conditions are met. For example, the UE 115 may perform a decoding procedure on the message (e.g., as described with reference to FIG. 2) and may determine whether the decoding procedure was successful. Then, the UE 115 may determine whether the message is a non-short message (e.g., based on the message including a short message field). If the decoding procedure was unsuccessful or if the message is not a non-short message, the UE 115 may return to process 305 (e.g., monitoring for another message).

At 315, if the one or more monitoring conditions are met (e.g., if the decoding procedure was successful and if the message is a non-short message), the UE 115 may extract a set of fields 320 (e.g., DCI fields) from the message. For example, the UE 115 may extract the set of fields 320 based on a type of RNTI corresponding to the message, based on a DCI type of the message, or both.

Although the set of fields 320 includes five fields 320 for illustration purposes, the UE 115 may extract any quantity of fields 320 from the message. The set of fields 320 may include fields such as field 320-a (e.g., a short message indicator field), field 320-b (e.g., a virtual resource block to physical resource block field), field 320-c (e.g., an MCS field), field 320-d (e.g., a transport block scale field), and field 320-e (e.g., reserved fields).

At 325, the UE 115 may compare a respective value corresponding to each field 320 with previous values corresponding to each field 320. In some cases, the UE 115 may maintain a record of respective set of previous values corresponding to each field 320 (e.g., in one or more registers or memories). For example, for each field 320, the UE 115 may store, in a first register, a value held by the field 320 in a previous message (e.g., a DCI message of the same DCI type and RNTI type) and may store, in a second register, a count value corresponding to a quantity of times that the DCI has been unchanged (e.g., for n decode procedures). If the UE 115 determines that a particular field 320 is a same value for a second decode, the UE 115 may increment the count value corresponding to the field 320. In some cases, the UE 115 may determine whether one or more bits of a field 320 are the same (e.g., using an XOR operation) across multiple decodes (e.g., rather than determining whether an entire field value is the same across the multiple decodes). Accordingly, as described herein, although some processes refer to a value of a field 320, these processes may be interpreted as referring to one or more bits of the field 320.

At 330, if the UE 115 determines that a field 320 of the set of fields 320 (e.g., field 320-c or field 320-d) is different from a corresponding field 320 of a previous message, the UE 115 may update the changed field 320 (e.g., in a register or memory array corresponding to the field 320). Further, the UE 115 may reset a count value corresponding to the field 320 to zero (e.g., representing that a quantity of zero times that the value has repeated).

At 335, the UE 115 may store a set of unchanged field contents. In some cases, the UE 115 may additionally or alternatively store changed field contents (e.g., in accordance with process 330). Thus, the UE 115 may maintain a record of previous field values in one or more memories (or registers) at the UE.

At 340, if the UE 115 determines that a field 320 of the set of fields 320 (e.g., field 320-a, field 320-b, or field 320-e) includes a value that is the same as a previous value for the field 320, the UE 115 may determine whether the field 320 has changed for a threshold quantity of consecutive decodes (e.g., K decodes). For example, the UE 115 may compare a count value corresponding to the field 320 with the threshold quantity of consecutive decodes.

At 345, if the count value is greater than (or in some cases, equal to) the threshold quantity, the UE 115 may determine to use a stored previous value corresponding to the field 320 as a known bit value for the field 320 (e.g., as described with reference to FIG. 2). The stored previous value may be referred to as one or more “learned” bits or one or more “known” bits in accordance with the learning scheme 300. That is, after determining that a field 320 includes a same value for a quantity of decodes (e.g., consecutive DCI message decodes) that exceeds a threshold, the UE 115 may begin to use one or more bits of the field 320 as known bits for other decode operations for similar messages.

At 350, if the count value is less than (or in some cases, equal to) the threshold quantity, the UE 115 may refrain from using the stored previous value as one or more “known bits” (e.g., until the count value satisfies the threshold quantity). In some cases, the threshold quantity of consecutive decodes may be a controllable value (e.g., controllable by the UE 115). Thus, the UE 115 may use the one or more bits as “known” bits if (and when) the one or more bits are consecutively the same for a threshold quantity of messages (e.g., DCI messages that are decoded at the UE).

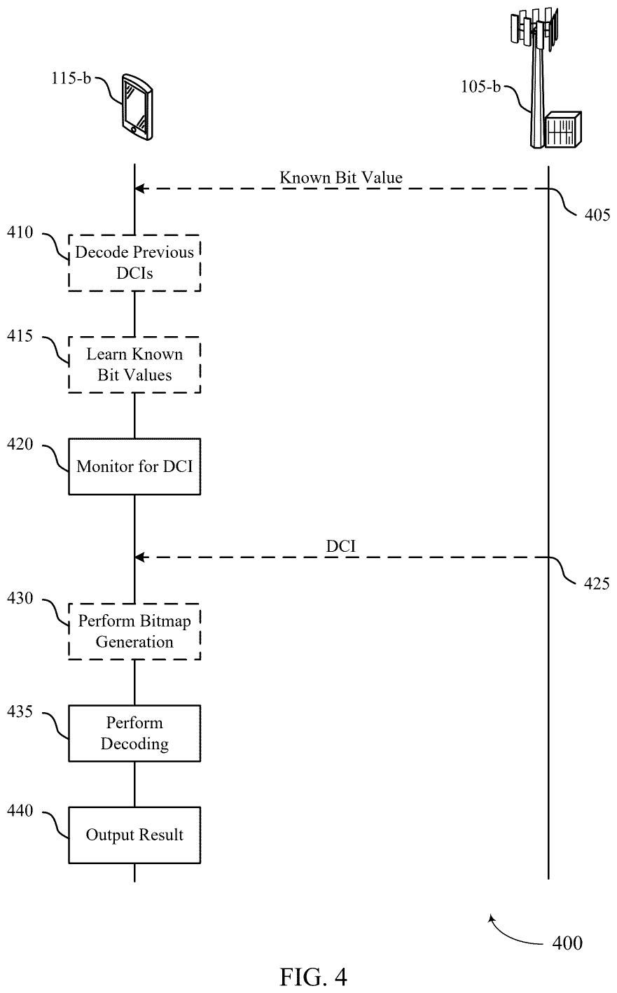

FIG. 4 shows an example of a process flow 400 that supports known bit exploitation in downlink channel decoding in accordance with one or more aspects of the present disclosure. The process flow 400 includes a UE 115-b and a network entity 105-b, which may be examples of the corresponding devices as described with respect to FIGS. 1-3. In the following description of the process flow 400, the operations between the UE 115-b and the network entity 105-b may be performed in a different order than the example order shown. Some operations may also be omitted from the process flow 400, and other operations may be added to the process flow 400. Further, although some operations or signaling may be shown to occur at different times for discussion purposes, these operations may actually occur at the same time.

At 405, the UE 115-b may receive signaling indicating at least a portion of one or more known bit values prior to monitoring for a DCI message. At 410, the UE 115-b may decode, prior to performing multiple decoding procedures, one or more previous DCI messages. The one or more previous DCI messages MAY indicate the one or more known bit values. At 415, the UE 115-b may learn at least the portion of the one or more known bit values according to one or more commonalities between multiple previous DCI messages of the one or more previous DCI messages. In some cases, at least a portion of the one or more known bit values may include one or more reserved bits, one or more padded bits, or a combination thereof.

At 420, the UE 115-b may monitor for the DCI message via a wireless channel. The DCI message may correspond to a DCI format. At 425, the UE 115-b may receive (e.g., from the network entity 105-b) the DCI message via the wireless channel. At 430, the UE 115-b may perform a bitmap generation procedure based on the one or more known bits values.

At 435, the UE 115-b may perform, in parallel, multiple decoding procedures on the DCI message. For example, the multiple decoding procedures may include at least a first decoding procedure that is based on a set of received bits of the DCI message. Additionally or alternatively, the multiple decoding procedures may include a second decoding procedure that is based on replacing at least the portion of the set of received bits with the one or more known bit values in accordance with the DCI format. For example, the second decoding procedure may include one or more steps that are similar to the first decoding procedure, but replacing at least the portion of the set of received bits with the one or more known bit values (e.g., performing a hypothesis where at least the portion of received bits may not be decoded, but rather these bits are assumed to be the one or more known bit values). In some cases, the second decoding procedure may be based on the bitmap generation procedure.

In some implementations, the first decoding procedure may be or may include a first polar decoding procedure. Additionally or alternatively, the second decoding procedure may be or may include a second polar decoding procedure. In some cases, the one or more known bit values may be associated with frozen bits in the second polar decoding procedure. Each known bit value of the one or more known bit values may include a respective logic state of a set of two logic states (e.g., ‘1’ or ‘0’).

At 440, the UE 115-b may output (such as to one or more higher processing or protocol layers) a result of at least one decoding procedure of the multiple decoding procedures based on a respective integrity check (e.g., a CRC) corresponding to each decoding procedure of the plurality of decoding procedures. For example, the UE 115-b may output a first result corresponding to the first decoding procedure and may output a second result corresponding to the second decoding procedure. In some cases, the UE 115-b may output a single result based on one or more integrity checks (e.g., the respective integrity check) corresponding to each decoding procedure.

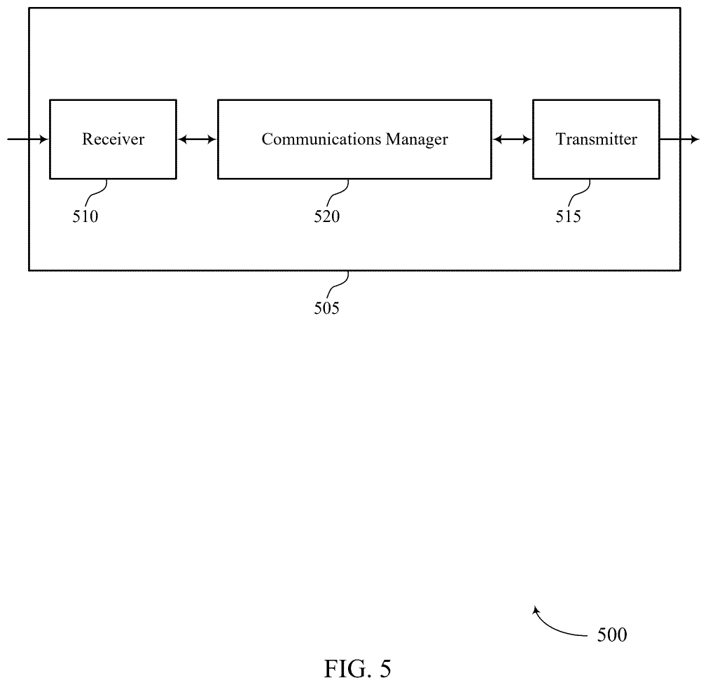

FIG. 5 shows a block diagram 500 of a device 505 that supports known bit exploitation in downlink channel decoding in accordance with one or more aspects of the present disclosure. The device 505 may be an example of aspects of a UE 115 as described herein. The device 505 may include a receiver 510, a transmitter 515, and a communications manager 520. The device 505, or one or more components of the device 505 (e.g., the receiver 510, the transmitter 515, the communications manager 520), may include at least one processor, which may be coupled with at least one memory, to, individually or collectively, support or enable the described techniques. Each of these components may be in communication with one another (e.g., via one or more buses).

The receiver 510 may provide a means for receiving information such as packets, user data, control information, or any combination thereof associated with various information channels (e.g., control channels, data channels, information channels related to known bit exploitation in downlink channel decoding). Information may be passed on to other components of the device 505. The receiver 510 may utilize a single antenna or a set of multiple antennas.

The transmitter 515 may provide a means for transmitting signals generated by other components of the device 505. For example, the transmitter 515 may transmit information such as packets, user data, control information, or any combination thereof associated with various information channels (e.g., control channels, data channels, information channels related to known bit exploitation in downlink channel decoding). In some examples, the transmitter 515 may be co-located with a receiver 510 in a transceiver module. The transmitter 515 may utilize a single antenna or a set of multiple antennas.

The communications manager 520, the receiver 510, the transmitter 515, or various combinations or components thereof may be examples of means for performing various aspects of known bit exploitation in downlink channel decoding as described herein. For example, the communications manager 520, the receiver 510, the transmitter 515, or various combinations or components thereof may be capable of performing one or more of the functions described herein.

In some examples, the communications manager 520, the receiver 510, the transmitter 515, or various combinations or components thereof may be implemented in hardware (e.g., in communications management circuitry). The hardware may include at least one of a processor, a digital signal processor (DSP), a central processing unit (CPU), an application-specific integrated circuit (ASIC), a field-programmable gate array (FPGA) or other programmable logic device, a microcontroller, discrete gate or transistor logic, discrete hardware components, or any combination thereof configured as or otherwise supporting, individually or collectively, a means for performing the functions described in the present disclosure. In some examples, at least one processor and at least one memory coupled with the at least one processor may be configured to perform one or more of the functions described herein (e.g., by one or more processors, individually or collectively, executing instructions stored in the at least one memory).

Additionally, or alternatively, the communications manager 520, the receiver 510, the transmitter 515, or various combinations or components thereof may be implemented in code (e.g., as communications management software or firmware) executed by at least one processor (e.g., referred to as a processor-executable code). If implemented in code executed by at least one processor, the functions of the communications manager 520, the receiver 510, the transmitter 515, or various combinations or components thereof may be performed by a general-purpose processor, a DSP, a CPU, an ASIC, an FPGA, a microcontroller, or any combination of these or other programmable logic devices (e.g., configured as or otherwise supporting, individually or collectively, a means for performing the functions described in the present disclosure).

In some examples, the communications manager 520 may be configured to perform various operations (e.g., receiving, obtaining, monitoring, outputting, transmitting) using or otherwise in cooperation with the receiver 510, the transmitter 515, or both. For example, the communications manager 520 may receive information from the receiver 510, send information to the transmitter 515, or be integrated in combination with the receiver 510, the transmitter 515, or both to obtain information, output information, or perform various other operations as described herein.

The communications manager 520 may support wireless communications in accordance with examples as disclosed herein. For example, the communications manager 520 is capable of, configured to, or operable to support a means for monitoring for a DCI message via a wireless channel, the DCI message corresponding to a DCI format. The communications manager 520 is capable of, configured to, or operable to support a means for performing, in parallel, a set of multiple decoding procedures on the DCI message, the set of multiple decoding procedures including at least a first decoding procedure that is based on a set of received bits of the DCI message and a second decoding procedure that is based on replacing at least a portion of the set of received bits with one or more known bit values in accordance with the DCI format. The communications manager 520 is capable of, configured to, or operable to support a means for outputting a result of at least one decoding procedure of the set of multiple decoding procedures based on a respective integrity check corresponding to each decoding procedure of the set of multiple decoding procedures.

By including or configuring the communications manager 520 in accordance with examples as described herein, the device 505 (e.g., at least one processor controlling or otherwise coupled with the receiver 510, the transmitter 515, the communications manager 520, or a combination thereof) may support techniques for known bit exploitation in downlink channel decoding, which may result in improved signaling efficiency which may reduce power consumption and more efficient utilization of communication resources, among other advantages.

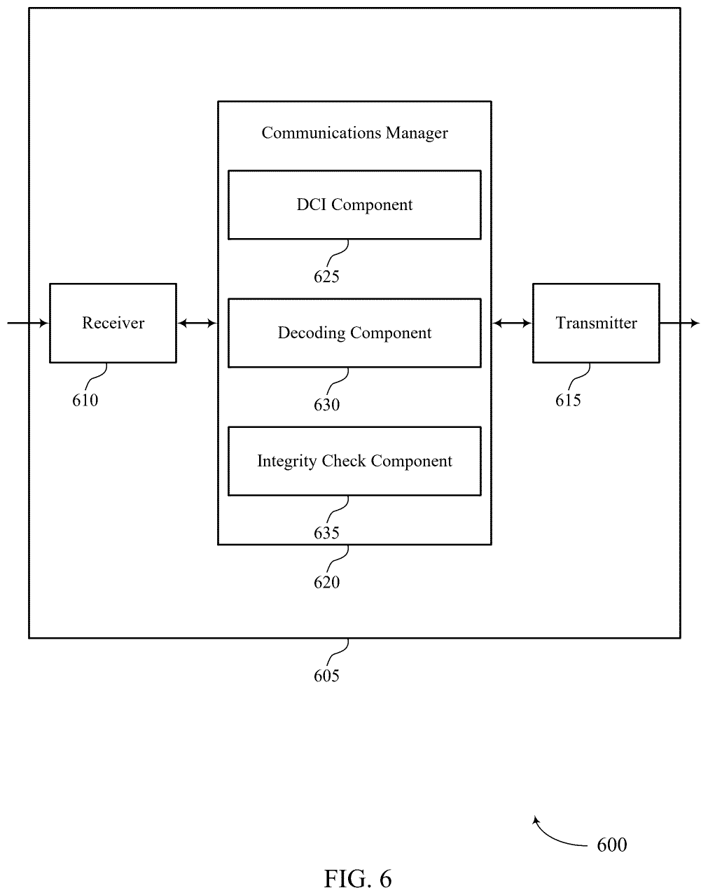

FIG. 6 shows a block diagram 600 of a device 605 that supports known bit exploitation in downlink channel decoding in accordance with one or more aspects of the present disclosure. The device 605 may be an example of aspects of a device 505 or a UE 115 as described herein. The device 605 may include a receiver 610, a transmitter 615, and a communications manager 620. The device 605, or one or more components of the device 605 (e.g., the receiver 610, the transmitter 615, the communications manager 620), may include at least one processor, which may be coupled with at least one memory, to support the described techniques. Each of these components may be in communication with one another (e.g., via one or more buses).

The receiver 610 may provide a means for receiving information such as packets, user data, control information, or any combination thereof associated with various information channels (e.g., control channels, data channels, information channels related to known bit exploitation in downlink channel decoding). Information may be passed on to other components of the device 605. The receiver 610 may utilize a single antenna or a set of multiple antennas.

The transmitter 615 may provide a means for transmitting signals generated by other components of the device 605. For example, the transmitter 615 may transmit information such as packets, user data, control information, or any combination thereof associated with various information channels (e.g., control channels, data channels, information channels related to known bit exploitation in downlink channel decoding). In some examples, the transmitter 615 may be co-located with a receiver 610 in a transceiver module. The transmitter 615 may utilize a single antenna or a set of multiple antennas.

The device 605, or various components thereof, may be an example of means for performing various aspects of known bit exploitation in downlink channel decoding as described herein. For example, the communications manager 620 may include a DCI component 625, a decoding component 630, an integrity check component 635, or any combination thereof. The communications manager 620 may be an example of aspects of a communications manager 520 as described herein. In some examples, the communications manager 620, or various components thereof, may be configured to perform various operations (e.g., receiving, obtaining, monitoring, outputting, transmitting) using or otherwise in cooperation with the receiver 610, the transmitter 615, or both. For example, the communications manager 620 may receive information from the receiver 610, send information to the transmitter 615, or be integrated in combination with the receiver 610, the transmitter 615, or both to obtain information, output information, or perform various other operations as described herein.

The communications manager 620 may support wireless communications in accordance with examples as disclosed herein. The DCI component 625 is capable of, configured to, or operable to support a means for monitoring for a DCI message via a wireless channel, the DCI message corresponding to a DCI format. The decoding component 630 is capable of, configured to, or operable to support a means for performing, in parallel, a set of multiple decoding procedures on the DCI message, the set of multiple decoding procedures including at least a first decoding procedure that is based on a set of received bits of the DCI message and a second decoding procedure that is based on replacing at least a portion of the set of received bits with one or more known bit values in accordance with the DCI format. The integrity check component 635 is capable of, configured to, or operable to support a means for outputting a result of at least one decoding procedure of the set of multiple decoding procedures based on a respective integrity check corresponding to each decoding procedure of the set of multiple decoding procedures.

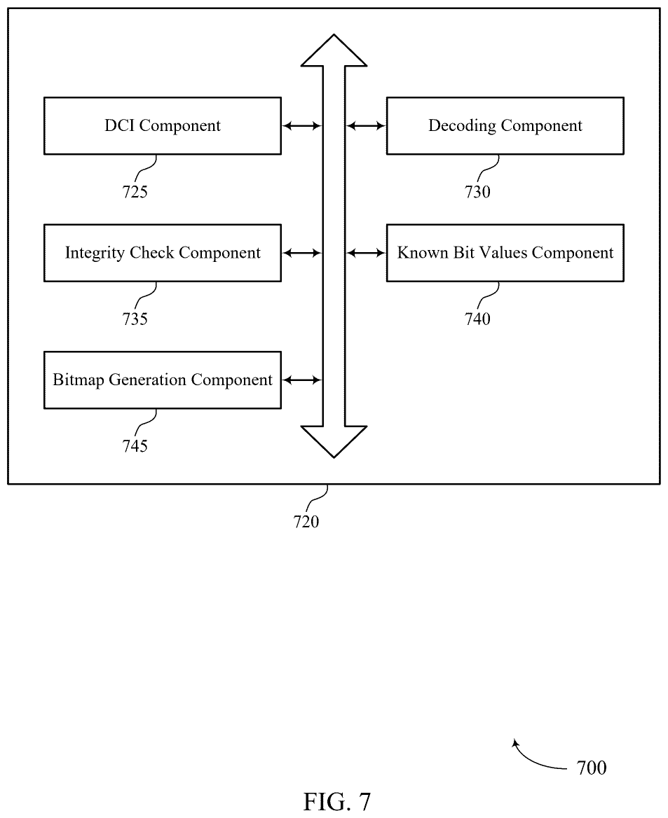

FIG. 7 shows a block diagram 700 of a communications manager 720 that supports known bit exploitation in downlink channel decoding in accordance with one or more aspects of the present disclosure. The communications manager 720 may be an example of aspects of a communications manager 520, a communications manager 620, or both, as described herein. The communications manager 720, or various components thereof, may be an example of means for performing various aspects of known bit exploitation in downlink channel decoding as described herein. For example, the communications manager 720 may include a DCI component 725, a decoding component 730, an integrity check component 735, a known bit values component 740, a bitmap generation component 745, or any combination thereof. Each of these components, or components or subcomponents thereof (e.g., one or more processors, one or more memories), may communicate, directly or indirectly, with one another (e.g., via one or more buses).

The communications manager 720 may support wireless communications in accordance with examples as disclosed herein. The DCI component 725 is capable of, configured to, or operable to support a means for monitoring for a DCI message via a wireless channel, the DCI message corresponding to a DCI format. The decoding component 730 is capable of, configured to, or operable to support a means for performing, in parallel, a set of multiple decoding procedures on the DCI message, the set of multiple decoding procedures including at least a first decoding procedure that is based on a set of received bits of the DCI message and a second decoding procedure that is based on replacing at least a portion of the set of received bits with one or more known bit values in accordance with the DCI format. The integrity check component 735 is capable of, configured to, or operable to support a means for outputting a result of at least one decoding procedure of the set of multiple decoding procedures based on a respective integrity check corresponding to each decoding procedure of the set of multiple decoding procedures.

In some examples, at least a portion of the one or more known bit values includes one or more reserved bits, one or more padded bits, or a combination thereof.

In some examples, the known bit values component 740 is capable of, configured to, or operable to support a means for receiving signaling indicating at least a portion of the one or more known bit values prior to monitoring for the DCI message.

In some examples, to support receiving the signaling indicating at least the portion of the one or more known bit values, the known bit values component 740 is capable of, configured to, or operable to support a means for decoding, prior to the set of multiple decoding procedures, one or more previous DCI messages, where the one or more previous DCI messages indicate the one or more known bit values.

In some examples, to support receiving the signaling indicating at least the portion of the one or more known bit values, the known bit values component 740 is capable of, configured to, or operable to support a means for learning at least the portion of the one or more known bit values according to one or more commonalities between a set of multiple previous DCI messages of the one or more previous DCI messages.

In some examples, the bitmap generation component 745 is capable of, configured to, or operable to support a means for performing a bitmap generation procedure based on the one or more known bit values, where the second decoding procedure is based on the bitmap generation procedure.

In some examples, the respective integrity check includes a cyclic redundancy check.

In some examples, one or both of the first decoding procedure or the second decoding procedure includes a polar decoding procedure.

In some examples, the one or more known bit values are associated with frozen bits in the polar decoding procedure. In some examples, each known bit value of the one or more known bit values includes a respective logic state of a set of two logic states.

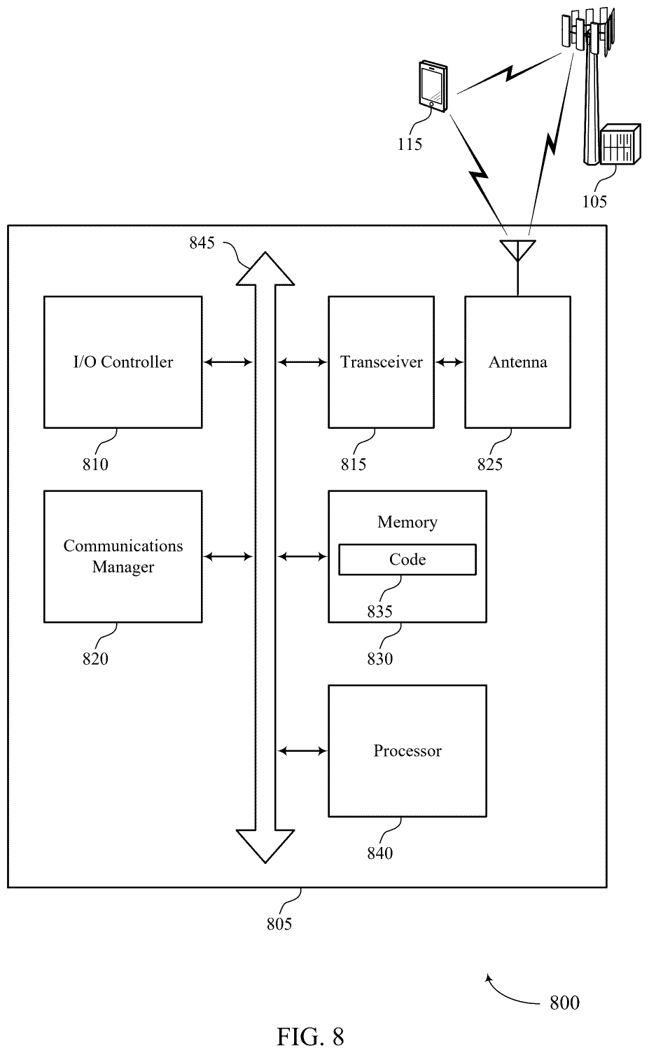

FIG. 8 shows a diagram of a system 800 including a device 805 that supports known bit exploitation in downlink channel decoding in accordance with one or more aspects of the present disclosure. The device 805 may be an example of or include components of a device 505, a device 605, or a UE 115 as described herein. The device 805 may communicate (e.g., wirelessly) with one or more other devices (e.g., network entities 105, UEs 115, or a combination thereof). The device 805 may include components for bi-directional voice and data communications including components for transmitting and receiving communications, such as a communications manager 820, an input/output (I/O) controller, such as an I/O controller 810, a transceiver 815, one or more antennas 825, at least one memory 830, code 835, and at least one processor 840. These components may be in electronic communication or otherwise coupled (e.g., operatively, communicatively, functionally, electronically, electrically) via one or more buses (e.g., a bus 845).

The I/O controller 810 may manage input and output signals for the device 805. The I/O controller 810 may also manage peripherals not integrated into the device 805. In some cases, the I/O controller 810 may represent a physical connection or port to an external peripheral. In some cases, the I/O controller 810 may utilize an operating system such as iOS®, ANDROID®, MS-DOS®, MS-WINDOWS®, OS/2®, UNIX®, LINUX®, or another known operating system. Additionally, or alternatively, the I/O controller 810 may represent or interact with a modem, a keyboard, a mouse, a touchscreen, or a similar device. In some cases, the I/O controller 810 may be implemented as part of one or more processors, such as the at least one processor 840. In some cases, a user may interact with the device 805 via the I/O controller 810 or via hardware components controlled by the I/O controller 810.

In some cases, the device 805 may include a single antenna. However, in some other cases, the device 805 may have more than one antenna, which may be capable of concurrently transmitting or receiving multiple wireless transmissions. The transceiver 815 may communicate bi-directionally via the one or more antennas 825 using wired or wireless links as described herein. For example, the transceiver 815 may represent a wireless transceiver and may communicate bi-directionally with another wireless transceiver. The transceiver 815 may also include a modem to modulate the packets, to provide the modulated packets to one or more antennas 825 for transmission, and to demodulate packets received from the one or more antennas 825. The transceiver 815, or the transceiver 815 and one or more antennas 825, may be an example of a transmitter 515, a transmitter 615, a receiver 510, a receiver 610, or any combination thereof or component thereof, as described herein.

The at least one memory 830 may include random access memory (RAM) and read-only memory (ROM). The at least one memory 830 may store computer-readable, computer-executable, or processor-executable code, such as the code 835. The code 835 may include instructions that, when executed by the at least one processor 840, cause the device 805 to perform various functions described herein. The code 835 may be stored in a non-transitory computer-readable medium such as system memory or another type of memory. In some cases, the code 835 may not be directly executable by the at least one processor 840 but may cause a computer (e.g., when compiled and executed) to perform functions described herein. In some cases, the at least one memory 830 may include, among other things, a basic I/O system (BIOS) which may control basic hardware or software operation such as the interaction with peripheral components or devices.

The at least one processor 840 may include one or more intelligent hardware devices (e.g., one or more general-purpose processors, one or more DSPs, one or more CPUs, one or more graphics processing units (GPUs), one or more neural processing units (NPUs) (also referred to as neural network processors or deep learning processors (DLPs)), one or more microcontrollers, one or more ASICs, one or more FPGAs, one or more programmable logic devices, discrete gate or transistor logic, one or more discrete hardware components, or any combination thereof). In some cases, the at least one processor 840 may be configured to operate a memory array using a memory controller. In some other cases, a memory controller may be integrated into the at least one processor 840. The at least one processor 840 may be configured to execute computer-readable instructions stored in a memory (e.g., the at least one memory 830) to cause the device 805 to perform various functions (e.g., functions or tasks supporting known bit exploitation in downlink channel decoding). For example, the device 805 or a component of the device 805 may include at least one processor 840 and at least one memory 830 coupled with or to the at least one processor 840, the at least one processor 840 and the at least one memory 830 configured to perform various functions described herein.

In some examples, the at least one processor 840 may include multiple processors and the at least one memory 830 may include multiple memories. One or more of the multiple processors may be coupled with one or more of the multiple memories, which may, individually or collectively, be configured to perform various functions described herein. In some examples, the at least one processor 840 may be a component of a processing system, which may refer to a system (such as a series) of machines, circuitry (including, for example, one or both of processor circuitry (which may include the at least one processor 840) and memory circuitry (which may include the at least one memory 830)), or components, that receives or obtains inputs and processes the inputs to produce, generate, or obtain a set of outputs. The processing system may be configured to perform one or more of the functions described herein. For example, the at least one processor 840 or a processing system including the at least one processor 840 may be configured to, configurable to, or operable to cause the device 805 to perform one or more of the functions described herein. Further, as described herein, being “configured to,” being “configurable to,” and being “operable to” may be used interchangeably and may be associated with a capability, when executing code 835 (e.g., processor-executable code) stored in the at least one memory 830 or otherwise, to perform one or more of the functions described herein.

The communications manager 820 may support wireless communications in accordance with examples as disclosed herein. For example, the communications manager 820 is capable of, configured to, or operable to support a means for monitoring for a DCI message via a wireless channel, the DCI message corresponding to a DCI format. The communications manager 820 is capable of, configured to, or operable to support a means for performing, in parallel, a set of multiple decoding procedures on the DCI message, the set of multiple decoding procedures including at least a first decoding procedure that is based on a set of received bits of the DCI message and a second decoding procedure that is based on replacing at least a portion of the set of received bits with one or more known bit values in accordance with the DCI format. The communications manager 820 is capable of, configured to, or operable to support a means for outputting a result of at least one decoding procedure of the set of multiple decoding procedures based on a respective integrity check corresponding to each decoding procedure of the set of multiple decoding procedures.

By including or configuring the communications manager 820 in accordance with examples as described herein, the device 805 may support techniques for known bit exploitation in downlink channel decoding, which may result in improved communication reliability, reduced latency, reduced power consumption, more efficient utilization of communication resources, improved coordination between devices, and improved utilization of processing capability, among other advantages.

In some examples, the communications manager 820 may be configured to perform various operations (e.g., receiving, monitoring, transmitting) using or otherwise in cooperation with the transceiver 815, the one or more antennas 825, or any combination thereof. Although the communications manager 820 is illustrated as a separate component, in some examples, one or more functions described with reference to the communications manager 820 may be supported by or performed by the at least one processor 840, the at least one memory 830, the code 835, or any combination thereof. For example, the code 835 may include instructions executable by the at least one processor 840 to cause the device 805 to perform various aspects of known bit exploitation in downlink channel decoding as described herein, or the at least one processor 840 and the at least one memory 830 may be otherwise configured to, individually or collectively, perform or support such operations.

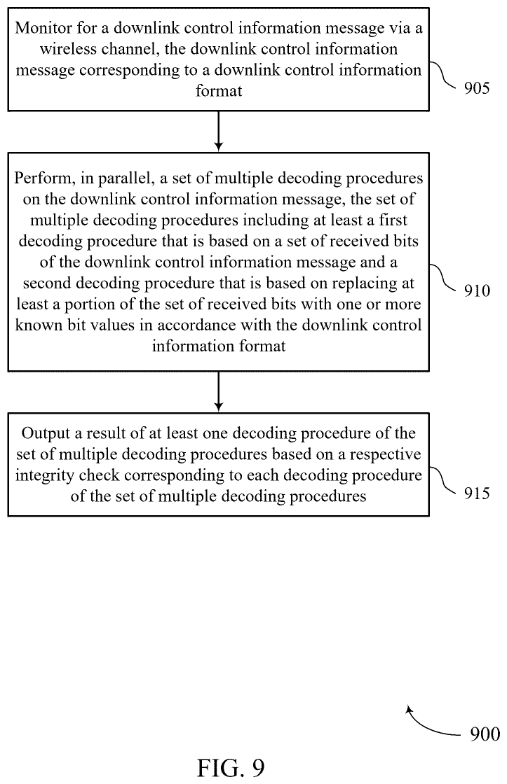

FIG. 9 shows a flowchart illustrating a method 900 that supports known bit exploitation in downlink channel decoding in accordance with one or more aspects of the present disclosure. The operations of the method 900 may be implemented by a UE or its components as described herein. For example, the operations of the method 900 may be performed by a UE 115 as described with reference to FIGS. 1 through 8. In some examples, a UE may execute a set of instructions to control the functional elements of the UE to perform the described functions. Additionally, or alternatively, the UE may perform aspects of the described functions using special-purpose hardware.

At 905, the method may include monitoring for a DCI message via a wireless channel, the DCI message corresponding to a DCI format. The operations of 905 may be performed in accordance with examples as disclosed herein. In some examples, aspects of the operations of 905 may be performed by a DCI component 725 as described with reference to FIG. 7.

At 910, the method may include performing, in parallel, a set of multiple decoding procedures on the DCI message, the set of multiple decoding procedures including at least a first decoding procedure that is based on a set of received bits of the DCI message and a second decoding procedure that is based on replacing at least a portion of the set of received bits with one or more known bit values in accordance with the DCI format. The operations of 910 may be performed in accordance with examples as disclosed herein. In some examples, aspects of the operations of 910 may be performed by a decoding component 730 as described with reference to FIG. 7.

At 915, the method may include outputting a result of at least one decoding procedure of the set of multiple decoding procedures based on a respective integrity check corresponding to each decoding procedure of the set of multiple decoding procedures. The operations of 915 may be performed in accordance with examples as disclosed herein. In some examples, aspects of the operations of 915 may be performed by an integrity check component 735 as described with reference to FIG. 7.

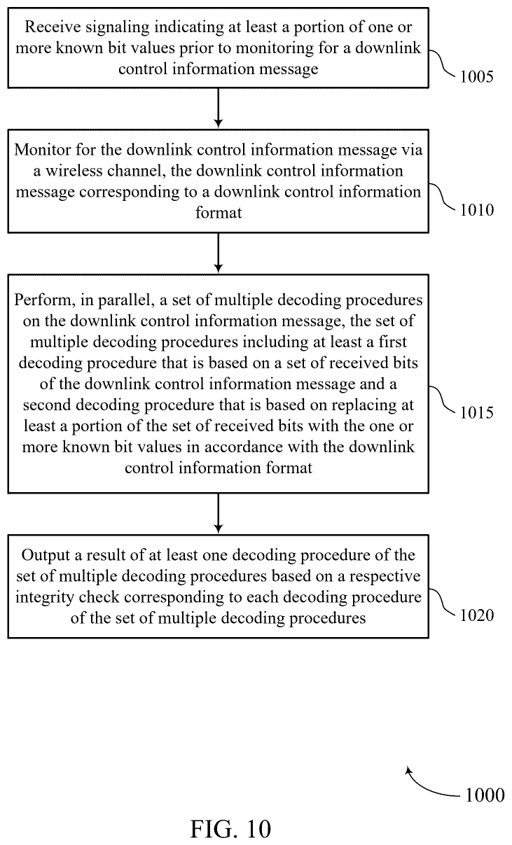

FIG. 10 shows a flowchart illustrating a method 1000 that supports known bit exploitation in downlink channel decoding in accordance with one or more aspects of the present disclosure. The operations of the method 1000 may be implemented by a UE or its components as described herein. For example, the operations of the method 1000 may be performed by a UE 115 as described with reference to FIGS. 1 through 8. In some examples, a UE may execute a set of instructions to control the functional elements of the UE to perform the described functions. Additionally, or alternatively, the UE may perform aspects of the described functions using special-purpose hardware.

At 1005, the method may include receiving signaling indicating at least a portion of one or more known bit values prior to monitoring for a DCI message. The operations of 1005 may be performed in accordance with examples as disclosed herein. In some examples, aspects of the operations of 1005 may be performed by a known bit values component 740 as described with reference to FIG. 7.

At 1010, the method may include monitoring for the DCI message via a wireless channel, the DCI message corresponding to a DCI format. The operations of 1010 may be performed in accordance with examples as disclosed herein. In some examples, aspects of the operations of 1010 may be performed by a DCI component 725 as described with reference to FIG. 7.

At 1015, the method may include performing, in parallel, a set of multiple decoding procedures on the DCI message, the set of multiple decoding procedures including at least a first decoding procedure that is based on a set of received bits of the DCI message and a second decoding procedure that is based on replacing at least a portion of the set of received bits with the one or more known bit values in accordance with the DCI format. The operations of 1015 may be performed in accordance with examples as disclosed herein. In some examples, aspects of the operations of 1015 may be performed by a decoding component 730 as described with reference to FIG. 7.

At 1020, the method may include outputting a result of at least one decoding procedure of the set of multiple decoding procedures based on a respective integrity check corresponding to each decoding procedure of the set of multiple decoding procedures. The operations of 1020 may be performed in accordance with examples as disclosed herein. In some examples, aspects of the operations of 1020 may be performed by an integrity check component 735 as described with reference to FIG. 7.

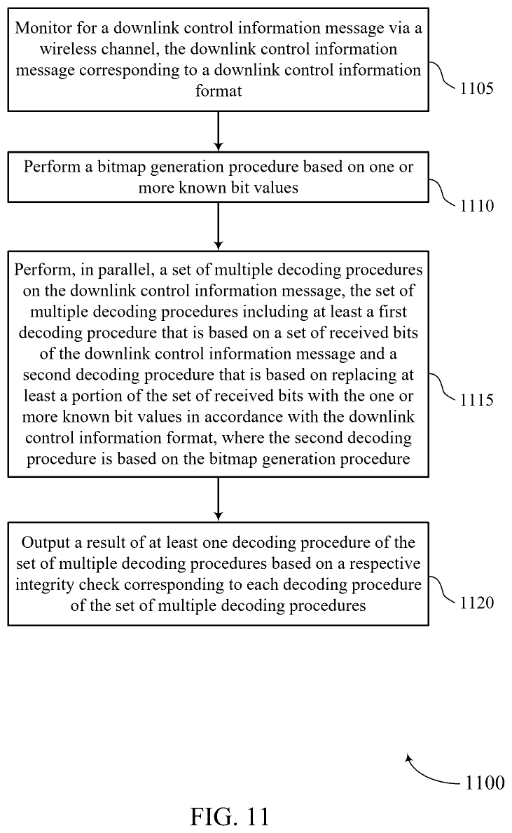

FIG. 11 shows a flowchart illustrating a method 1100 that supports known bit exploitation in downlink channel decoding in accordance with one or more aspects of the present disclosure. The operations of the method 1100 may be implemented by a UE or its components as described herein. For example, the operations of the method 1100 may be performed by a UE 115 as described with reference to FIGS. 1 through 8. In some examples, a UE may execute a set of instructions to control the functional elements of the UE to perform the described functions. Additionally, or alternatively, the UE may perform aspects of the described functions using special-purpose hardware.

At 1105, the method may include monitoring for a DCI message via a wireless channel, the DCI message corresponding to a DCI format. The operations of 1105 may be performed in accordance with examples as disclosed herein. In some examples, aspects of the operations of 1105 may be performed by a DCI component 725 as described with reference to FIG. 7.

At 1110, the method may include performing a bitmap generation procedure based on one or more known bit values. The operations of 1110 may be performed in accordance with examples as disclosed herein. In some examples, aspects of the operations of 1110 may be performed by a bitmap generation component 745 as described with reference to FIG. 7.

At 1115, the method may include performing, in parallel, a set of multiple decoding procedures on the DCI message, the set of multiple decoding procedures including at least a first decoding procedure that is based on a set of received bits of the DCI message and a second decoding procedure that is based on replacing at least a portion of the set of received bits with the one or more known bit values in accordance with the DCI format, where the second decoding procedure is based on the bitmap generation procedure. The operations of 1115 may be performed in accordance with examples as disclosed herein. In some examples, aspects of the operations of 1115 may be performed by a decoding component 730 as described with reference to FIG. 7.

At 1120, the method may include outputting a result of at least one decoding procedure of the set of multiple decoding procedures based on a respective integrity check corresponding to each decoding procedure of the set of multiple decoding procedures. The operations of 1120 may be performed in accordance with examples as disclosed herein. In some examples, aspects of the operations of 1120 may be performed by an integrity check component 735 as described with reference to FIG. 7.

The following provides an overview of aspects of the present disclosure:

Aspect 1: A method for wireless communications at a wireless device, comprising: monitoring for a downlink control information message via a wireless channel, the downlink control information message corresponding to a downlink control information format; performing, in parallel, a plurality of decoding procedures on the downlink control information message, the plurality of decoding procedures including at least a first decoding procedure that is based at least in part on a set of received bits of the downlink control information message and a second decoding procedure that is based at least in part on replacing at least a portion of the set of received bits with one or more known bit values in accordance with the downlink control information format; and outputting a result of at least one decoding procedure of the plurality of decoding procedures based at least in part on a respective integrity check corresponding to each decoding procedure of the plurality of decoding procedures.

Aspect 2: The method of aspect 1, wherein at least a portion of the one or more known bit values comprises one or more reserved bits, one or more padded bits, or a combination thereof.

Aspect 3: The method of any of aspects 1 through 2, further comprising: receiving signaling indicating at least a portion of the one or more known bit values prior to monitoring for the downlink control information message.

Aspect 4: The method of aspect 3, wherein receiving the signaling indicating at least the portion of the one or more known bit values comprises: decoding, prior to the plurality of decoding procedures, one or more previous downlink control information messages, wherein the one or more previous downlink control information messages indicate the one or more known bit values.

Aspect 5: The method of aspect 4, wherein receiving the signaling indicating at least the portion of the one or more known bit values further comprises: learning at least the portion of the one or more known bit values according to one or more commonalities between a plurality of previous downlink control information messages of the one or more previous downlink control information messages.

Aspect 6: The method of any of aspects 1 through 5, further comprising: performing a bitmap generation procedure based at least in part on the one or more known bit values, wherein the second decoding procedure is based at least in part on the bitmap generation procedure.

Aspect 7: The method of any of aspects 1 through 6, wherein the respective integrity check comprises a cyclic redundancy check.

Aspect 8: The method of any of aspects 1 through 7, wherein one or both of the first decoding procedure or the second decoding procedure comprises a polar decoding procedure.

Aspect 9: The method of aspect 8, wherein the one or more known bit values are associated with frozen bits in the polar decoding procedure, and each known bit value of the one or more known bit values comprises a respective logic state of a set of two logic states.

Aspect 10: A wireless device for wireless communications, comprising one or more memories storing processor-executable code, and one or more processors coupled with the one or more memories and individually or collectively operable to execute the code to cause the wireless device to perform a method of any of aspects 1 through 9.

Aspect 11: A wireless device for wireless communications, comprising at least one means for performing a method of any of aspects 1 through 9.

Aspect 12: A non-transitory computer-readable medium storing code for wireless communications, the code comprising instructions executable by one or more processors to perform a method of any of aspects 1 through 9.

It should be noted that the methods described herein describe possible implementations. The operations and the steps may be rearranged or otherwise modified and other implementations are possible. Further, aspects from two or more of the methods may be combined.

Although aspects of an LTE, LTE-A, LTE-A Pro, or NR system may be described for purposes of example, and LTE, LTE-A, LTE-A Pro, or NR terminology may be used in much of the description, the techniques described herein are applicable beyond LTE, LTE-A, LTE-A Pro, or NR networks. For example, the described techniques may be applicable to various other wireless communications systems such as Ultra Mobile Broadband (UMB), Institute of Electrical and Electronics Engineers (IEEE) 802.11 (Wi-Fi), IEEE 802.16 (WiMAX), IEEE 802.20, Flash-OFDM, as well as other systems and radio technologies not explicitly mentioned herein.

Information and signals described herein may be represented using any of a variety of different technologies and techniques. For example, data, instructions, commands, information, signals, bits, symbols, and chips that may be referenced throughout the description may be represented by voltages, currents, electromagnetic waves, magnetic fields or particles, optical fields or particles, or any combination thereof.

The various illustrative blocks and components described in connection with the disclosure herein may be implemented or performed using a general-purpose processor, a DSP, an ASIC, a CPU, a graphics processing unit (GPU), a neural processing unit (NPU), an FPGA or other programmable logic device, discrete gate or transistor logic, discrete hardware components, or any combination thereof designed to perform the functions described herein. A general-purpose processor may be a microprocessor but, in the alternative, the processor may be any processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration). Any functions or operations described herein as being capable of being performed by a processor may be performed by multiple processors that, individually or collectively, are capable of performing the described functions or operations.

The functions described herein may be implemented using hardware, software executed by a processor, firmware, or any combination thereof. If implemented using software executed by a processor, the functions may be stored as or transmitted using one or more instructions or code of a computer-readable medium. Other examples and implementations are within the scope of the disclosure and appended claims. For example, due to the nature of software, functions described herein may be implemented using software executed by a processor, hardware, firmware, hardwiring, or combinations of any of these. Features implementing functions may also be physically located at various positions, including being distributed such that portions of functions are implemented at different physical locations.

Computer-readable media includes both non-transitory computer storage media and communication media including any medium that facilitates transfer of a computer program from one location to another. A non-transitory storage medium may be any available medium that may be accessed by a general-purpose or special-purpose computer. By way of example, and not limitation, non-transitory computer-readable media may include RAM, ROM, electrically erasable programmable ROM (EEPROM), flash memory, compact disk (CD) ROM or other optical disk storage, magnetic disk storage or other magnetic storage devices, or any other non-transitory medium that may be used to carry or store desired program code means in the form of instructions or data structures and that may be accessed by a general-purpose or special-purpose computer or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of computer-readable medium. Disk and disc, as used herein, include CD, laser disc, optical disc, digital versatile disc (DVD), floppy disk, and Blu-ray disc. Disks may reproduce data magnetically, and discs may reproduce data optically using lasers. Combinations of the above are also included within the scope of computer-readable media. Any functions or operations described herein as being capable of being performed by a memory may be performed by multiple memories that, individually or collectively, are capable of performing the described functions or operations.

As used herein, including in the claims, “or” as used in a list of items (e.g., a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an example step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” and “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

The term “determine” or “determining” encompasses a variety of actions and, therefore, “determining” can include calculating, computing, processing, deriving, investigating, looking up (such as via looking up in a table, a database, or another data structure), ascertaining, and the like. Also, “determining” can include receiving (e.g., receiving information), accessing (e.g., accessing data stored in memory), and the like. Also, “determining” can include resolving, obtaining, selecting, choosing, establishing, and other such similar actions.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label or other subsequent reference label.

The description set forth herein, in connection with the appended drawings, describes example configurations and does not represent all the examples that may be implemented or that are within the scope of the claims. The term “example” used herein means “serving as an example, instance, or illustration” and not “preferred” or “advantageous over other examples.” The detailed description includes specific details for the purpose of providing an understanding of the described techniques. These techniques, however, may be practiced without these specific details. In some figures, known structures and devices are shown in block diagram form in order to avoid obscuring the concepts of the described examples.

The description herein is provided to enable a person having ordinary skill in the art to make or use the disclosure. Various modifications to the disclosure will be apparent to a person having ordinary skill in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A wireless device, comprising:
one or more memories storing processor-executable code; and
one or more processors coupled with the one or more memories and individually or collectively operable to execute the code to cause the wireless device to:
monitor for a downlink control information message via a wireless channel, the downlink control information message corresponding to a downlink control information format;
perform, in parallel, a plurality of decoding procedures on the downlink control information message, the plurality of decoding procedures including at least a first decoding procedure that is based at least in part on a set of received bits of the downlink control information message and a second decoding procedure that is based at least in part on replacing at least a portion of the set of received bits with one or more known bit values in accordance with the downlink control information format; and
output a result of at least one decoding procedure of the plurality of decoding procedures based at least in part on a respective integrity check corresponding to each decoding procedure of the plurality of decoding procedures.

2. The wireless device of claim 1, wherein at least a portion of the one or more known bit values comprises one or more reserved bits, one or more padded bits, or a combination thereof.

3. The wireless device of claim 1, wherein the one or more processors are individually or collectively further operable to execute the code to cause the wireless device to:
receive signaling indicating at least a portion of the one or more known bit values prior to monitoring for the downlink control information message.

4. The wireless device of claim 3, wherein, to receive the signaling indicating at least the portion of the one or more known bit values, the one or more processors are individually or collectively operable to execute the code to cause the wireless device to:
decode, prior to the plurality of decoding procedures, one or more previous downlink control information messages, wherein the one or more previous downlink control information messages indicate the one or more known bit values.

5. The wireless device of claim 4, wherein, to receive the signaling indicating at least the portion of the one or more known bit values, the one or more processors are individually or collectively further operable to execute the code to cause the wireless device to:
learn at least the portion of the one or more known bit values according to one or more commonalities between a plurality of previous downlink control information messages of the one or more previous downlink control information messages.

6. The wireless device of claim 1, wherein the one or more processors are individually or collectively further operable to execute the code to cause the wireless device to:
perform a bitmap generation procedure based at least in part on the one or more known bit values, wherein the second decoding procedure is based at least in part on the bitmap generation procedure.

7. The wireless device of claim 1, wherein the respective integrity check comprises a cyclic redundancy check.

8. The wireless device of claim 1, wherein one or both of the first decoding procedure or the second decoding procedure comprises a polar decoding procedure.

9. The wireless device of claim 8, wherein:
the one or more known bit values are associated with frozen bits in the polar decoding procedure, and
each known bit value of the one or more known bit values comprises a respective logic state of a set of two logic states.

10. A method for wireless communications at a wireless device, comprising:
monitoring for a downlink control information message via a wireless channel, the downlink control information message corresponding to a downlink control information format;
performing, in parallel, a plurality of decoding procedures on the downlink control information message, the plurality of decoding procedures including at least a first decoding procedure that is based at least in part on a set of received bits of the downlink control information message and a second decoding procedure that is based at least in part on replacing at least a portion of the set of received bits with one or more known bit values in accordance with the downlink control information format; and
outputting a result of at least one decoding procedure of the plurality of decoding procedures based at least in part on a respective integrity check corresponding to each decoding procedure of the plurality of decoding procedures.

11. The method of claim 10, wherein at least a portion of the one or more known bit values comprises one or more reserved bits, one or more padded bits, or a combination thereof.

12. The method of claim 10, further comprising:
receiving signaling indicating at least a portion of the one or more known bit values prior to monitoring for the downlink control information message.

13. The method of claim 12, wherein receiving the signaling indicating at least the portion of the one or more known bit values comprises:
decoding, prior to the plurality of decoding procedures, one or more previous downlink control information messages, wherein the one or more previous downlink control information messages indicate the one or more known bit values.

14. The method of claim 13, wherein receiving the signaling indicating at least the portion of the one or more known bit values further comprises:
learning at least the portion of the one or more known bit values according to one or more commonalities between a plurality of previous downlink control information messages of the one or more previous downlink control information messages.

15. The method of claim 10, further comprising:
performing a bitmap generation procedure based at least in part on the one or more known bit values, wherein the second decoding procedure is based at least in part on the bitmap generation procedure.

16. The method of claim 10, wherein the respective integrity check comprises a cyclic redundancy check.

17. The method of claim 10, wherein one or both of the first decoding procedure or the second decoding procedure comprises a polar decoding procedure.

18. A non-transitory computer-readable medium storing code for wireless communications, the code comprising instructions executable by one or more processors to:
monitor for a downlink control information message via a wireless channel, the downlink control information message corresponding to a downlink control information format;
perform, in parallel, a plurality of decoding procedures on the downlink control information message, the plurality of decoding procedures including at least a first decoding procedure that is based at least in part on a set of received bits of the downlink control information message and a second decoding procedure that is based at least in part on replacing at least a portion of the set of received bits with one or more known bit values in accordance with the downlink control information format; and
output a result of at least one decoding procedure of the plurality of decoding procedures based at least in part on a respective integrity check corresponding to each decoding procedure of the plurality of decoding procedures.

19. The non-transitory computer-readable medium of claim 18, wherein at least a portion of the one or more known bit values comprises one or more reserved bits, one or more padded bits, or a combination thereof.

20. The non-transitory computer-readable medium of claim 18, wherein the instructions are further executable by the one or more processors to:
receive signaling indicating at least a portion of the one or more known bit values prior to monitoring for the downlink control information message.
